(19) United States
(12) Patent Application Publication
(10) Pub. No.: US 2023/0402539 A1
(43) Pub. Date: Dec. 14, 2023

(54) SEMICONDUCTOR DEVICE

(71) Applicant: ROHM CO., LTD., Kyoto-shi (JP)

(72) Inventors: Akihiro SAITO, Kyoto-shi (JP); Masatsugu YUTANI, Kyoto-shi (JP)

(73) Assignee: ROHM CO., LTD., Kyoto-shi (JP)

(21) Appl. No.: 18/457,347

(22) Filed: Aug. 29, 2023

Related U.S. Application Data
(63) Continuation of application No. PCT/JP2022/005666, filed on Feb. 14, 2022.

(30) Foreign Application Priority Data
Mar. 30, 2021 (JP) 2021-058601

(51) Int. Cl. H01L 29/78; H01L 29/06; H01L 29/423

(52) U.S. Cl. CPC H01L 29/7813; H01L 29/0696; H01L 29/4236

(57) ABSTRACT

A semiconductor device includes a semiconductor chip, a first conductive film formed on a first principal surface of the semiconductor chip, a fourth conductive film formed on a second principal surface of the semiconductor chip, a third impurity region formed in the semiconductor chip, a vertical-type semiconductor element structure which includes a gate trench formed in an active region and arrayed at a cell pitch and allows a current to flow between the first conductive film and the fourth conductive film, a first outer peripheral trench which is annular and formed in the outer peripheral region, and a plurality of second outer peripheral trenches which are annular and formed in the outer peripheral region further outside than the first outer peripheral trench, in which a first outer peripheral pitch between the first outer peripheral trench and the second outer peripheral trench is not less than 2 times and not more than 4 times the cell pitch.

### CROSS-REFERENCE TO RELATED APPLICATIONS

The present application is a continuation of PCT International Application No. PCT/JP2022/005666, filed on Feb. 14, 2022, which corresponds to Japanese Patent Application No. 2021-058601 filed with the Japan Patent Office on Mar. 30, 2021, and the entire disclosure of each application is incorporated herein by reference.

### BACKGROUND OF THE INVENTION

### 1. Field of the Invention

The present disclosure relates to a semiconductor device.

### 2. Description of the Related Art

For example, Japanese Translation of Unexamined International Application No. 2006-520091 discloses a trench gate vertical-type MOSFET including an epitaxial layer in which an active cell array and a gate bus area are formed, a gate trench which is formed in the active cell array, a gate oxide film which is formed in the gate trench, a gate electrode which is constituted of polysilicon embedded in the gate trench, a trench which is formed in the gate bus area and connected to the gate trench, and a gate bus which is constituted of polysilicon embedded in the trench so as to cover a front surface of the epitaxial layer in the gate bus area.

### BRIEF DESCRIPTION OF THE DRAWINGS

FIG. 1 is a schematic plan view of a semiconductor device according to a preferred embodiment of the present disclosure.

FIG. 2 is a view which shows a planar structure of an active region in FIG. 1.

FIG. 3 is a view which shows a cross section III-III in FIG. 2 (first mode).

FIG. 4 is a view which shows a cross section III-III in FIG. 2 (second mode).

FIG. 5 is a view which shows a planar structure of an outer peripheral region in FIG. 1.

FIG. 6 is an enlarged view of a portion which is surrounded by a double dot & dashed line VI in FIG. 5.

FIG. 7 is an enlarged view of a portion which is surrounded by a double dot & dashed line VII in FIG. 5.

FIG. 8 is a view which shows a cross section VIII-VIII in FIG. 6.

FIG. 9 is a view which shows a cross section IX-IX in FIG. 7.

FIG. 10 is a view for comparing withstand voltages of semiconductor elements according to Sample 1 to Sample 4.

FIG. 11 is a schematic plan view of a semiconductor element according to Sample 5 to Sample 8.

FIG. 12 is a schematic sectional view of the semiconductor element according to Sample 5.

FIG. 13 is a schematic sectional view of the semiconductor element according to Sample 6.

FIG. 14 is a schematic sectional view of the semiconductor element according to Sample 7.

FIG. 15 is a schematic sectional view of the semiconductor element according to Sample 8.

FIG. 16 is a schematic plan view of a semiconductor element according to Sample 9.

FIG. 17 is a schematic sectional view of the semiconductor element according to Sample 9.

FIG. 18 is a schematic plan view of a semiconductor element according to Sample 10.

FIG. 19 is a schematic sectional view of the semiconductor element according to Sample 10.

FIG. 20 is a schematic plan view of a semiconductor element according to Sample 11.

FIG. 21 is a schematic sectional view of the semiconductor element according to Sample 11.

FIG. 22 is a schematic sectional view of a semiconductor element according to Sample 12.

FIG. 23 is a view for comparing withstand voltages of the semiconductor elements according to Sample 5 to Sample 7 and those according to Sample 9 to Sample 11.

FIG. 24 is a schematic view which shows an extension of a depletion layer in an outer peripheral region of the semiconductor element according to Sample 5.

FIG. 25 is a schematic view which shows an extension of the depletion layer in an outer peripheral region of the semiconductor element according to Sample 6.

FIG. 26 is a schematic view which shows an extension of the depletion layer in an outer peripheral region of the semiconductor element according to Sample 7.

FIG. 27 is a schematic view which shows an extension of the depletion layer in an outer peripheral region of the semiconductor element according to Sample 9.

FIG. 28 is a schematic view which shows an extension of the depletion layer in an outer peripheral region of the semiconductor element according to Sample 10.

FIG. 29 is a schematic view which shows an extension of the depletion layer in an outer peripheral region of the semiconductor element according to Sample 11.

FIG. 30 is a schematic sectional view of a semiconductor element according to Sample 13.

FIG. 31 is a schematic sectional view of a semiconductor element according to Sample 14.

FIG. 32 is a schematic sectional view of a semiconductor element according to Sample 15.

FIG. 33 is a schematic sectional view of a semiconductor element according to Sample 16.

FIG. 34 is a view which shows a relationship between a first outer peripheral pitch and a device withstand voltage.

FIG. 35 is a view which shows a relationship between a second outer peripheral pitch and the device withstand voltage.

FIG. 36 is a view which shows a relationship between a third outer peripheral pitch and the device withstand voltage.

FIG. 37 is a schematic sectional view of a semiconductor element according to a preferred embodiment of the present disclosure.

### DETAILED DESCRIPTION OF EMBODIMENTS

Next, a detailed description will be given of the preferred embodiment of the present disclosure with reference to attached drawings. It is noted that in the following detailed description, although a constituent of a name to which an ordinal number is given is provided in a plural number, the ordinal number is not necessarily in agreement with an ordinal number of a constituent described in a claim.

### [Entire Constitution of Semiconductor Device 1]

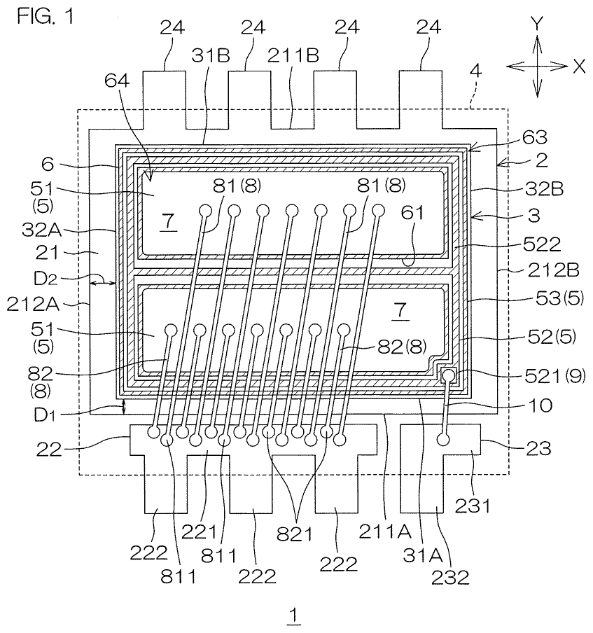

FIG. 1 is a schematic plan view of a semiconductor device 1 according to a preferred embodiment of the present disclosure. For clarity, in FIG. 1, a package 4 is indicated by an imaginary line (broken line) and the other constitutions are indicated by a solid line.

The semiconductor device 1 includes a lead frame 2, a semiconductor element 3 and the package 4.

The lead frame 2 is formed in a metal plate shape. The lead frame 2 is formed with a thin metal plate such as a Cu plate in a rectangular shape in a plan view by processing such as punching, cutting and bending. Accordingly, a material of the lead frame 2 is Cu as a main composition. The material of the lead frame 2 is not limited thereto.

The lead frame 2 may include a die pad portion 21, a first lead portion 22, a second lead portion 23 and a third lead portion 24. In the preferred embodiment, the first lead portion 22, the second lead portion 23 and the third lead portion 24 may be respectively referred to as a source lead portion, a gate lead portion and a drain lead portion. Further, the first lead portion 22, the second lead portion 23 and the third lead portion 24 have a portion which is exposed from the package 4 and connected to an external circuit of the semiconductor device 1 and, therefore, may be referred to as a first electrode (source electrode), a second electrode (gate electrode) and a third electrode (drain electrode).

The die pad portion 21 has a quadrilateral shape having a pair of first sides 211A, 211B extending in a first direction X in a plan view and a pair of second sides 212A, 212B extending in a direction which intersects the first direction X (direction orthogonal thereto in the preferred embodiment).

The first lead portion 22, the second lead portion 23 and the third lead portion 24 are disposed around the die pad portion 21. In the preferred embodiment, the first lead portion 22, the second lead portion 23 and the third lead portion 24 are disposed adjacent to the first sides 211A, 211B of the die pad portion 21. More specifically, the first lead portion 22 and the second lead portion 23 are disposed adjacent to the first side 211A which is one side of the die pad portion 21, and the third lead portion 24 is disposed adjacent to the first side 211B which is the other side of the die pad. That is, the first lead portion 22 and the second lead portion 23 are disposed at the opposite side of the third lead portion 24 across the die pad portion 21.

The first lead portion 22 is formed separated from the die pad portion 21. The first lead portion 22 may include a first pad portion 221 and a first lead 222. The first pad portion 221 is formed in an approximately rectangular shape which is long along the first side 211A of the die pad portion 21 in a plan view. The first lead 222 is formed integrally with the first pad portion 221 and extends from the first pad portion 221 in a direction which intersects a longitudinal direction of the first pad portion 221. The first lead 222 is formed in a plural number (three in the preferred embodiment). The plurality of first leads 222 are arrayed at an interval from each other along a longitudinal direction of a common first pad portion 221 and connected to the common first pad portion 221.

The second lead portion 23 is formed separated from the die pad portion 21 and the first lead portion 22. The second lead portion 23 may include a second pad portion 231 and a second lead 232. The second pad portion 231 is formed in an approximately rectangular shape which is long along the first side 211A of the die pad portion 21. The second lead 232 is formed integrally with the second pad portion 231 and extends from the second pad portion 231 in a direction which intersects a longitudinal direction of the second pad portion 231. The second lead 232 is connected to the second pad portion 231 on a one-to-one basis. In the preferred embodiment, the second lead portion 23 is disposed in the vicinity of one end portion (one corner of the die pad portion 21) of the first side 211A which is one side of the die pad portion 21, and the first lead portion 22 extends along the first side 211A of the die pad portion 21 from one end portion to the other end portion.

Unlike the first lead portion 22 or the second lead portion 23, the third lead portion 24 is formed integrally with the die pad portion 21. The third lead portion 24 extends from the first side 211B which is the other side of the die pad portion 21 in a direction intersecting the first side 211B. The third lead portion 24 is formed in a plural number (four in the preferred embodiment). The plurality of third lead portions 24 are arrayed at an interval from each other along the first side 211B of the die pad portion 21.

The semiconductor element 3 is disposed on the die pad portion 21 of the lead frame 2 and supported by the die pad portion 21. The semiconductor element 3 is formed in a quadrilateral shape having a pair of first end surfaces 31A, 31B and a pair of second end surfaces 32A, 32B in a plan view and smaller than the die pad portion 21. In the preferred embodiment, the semiconductor element 3 is disposed on the die pad portion 21 so that the first end surfaces 31A, 31B are parallel to the first sides 211A, 211B of the die pad portion 21 and the second end surfaces 32A, 32B are parallel to the second sides 212A, 212B of the die pad portion 21. A first distance D₁ between the first sides 211A, 211B of the die pad portion 21 and the first end surfaces 31A, 31B of the semiconductor element 3 is made narrower than a second distance D₂ between the second sides 212A, 212B of the die pad portion 21 and the second end surfaces 32A, 32B of the semiconductor element 3. For example, the first distance D₁ may be not more than ½ of the second distance D₂.

A conductive film 5 as an example of the front surface electrode and an insulating film 6 are formed in one surface (upper surface in the preferred embodiment) of the semiconductor element 3. The conductive film 5 is partially covered by the insulating film 6. In FIG. 1, a portion of the conductive film 5 which is covered by the insulating film 6 is shown with hatching, and a portion which is exposed from the insulating film 6 is shown by a white area. The conductive film 5 is a portion to which a first wire 8 and a second wire 10 to be described later are connected and may be referred to as an electrode film or a front surface electrode film.

The conductive film 5 is formed substantially in an entire area of an upper surface of the semiconductor element 3. The conductive film 5 may include a first conductive film 51, a second conductive film 52 and a third conductive film 53. The first conductive film 51, the second conductive film 52 and the third conductive film 53 are formed separated from each other.

The first conductive film 51 is formed in a plural number. The plurality of first conductive films 51 are formed adjacent to each other in a direction along the second end surfaces 32A, 32B of the semiconductor element 3, and a clearance region 61 is formed between the mutually adjacent first conductive films 51. Further, a region around the first conductive film 51 may be an outer peripheral region 63. That is, where a region which forms the first conductive film 51 (a region covered by the first conductive film 51) is referred to as an active region 64, the outer peripheral region 63 may be an outer peripheral region 63 which surrounds the active region 64. Further, in the preferred embodiment, the outer peripheral region 63 is in an annular shape which is formed along an outer periphery of the semiconductor element 3.

In the preferred embodiment, each of the first conductive films 51 is formed in a rectangular shape in a plan view long along the first end surfaces 31A, 31B of the semiconductor element 3. A part of the first conductive film 51 is exposed from the insulating film 6 as a first pad 7.

The first wire 8 is connected to the first pad 7. In the preferred embodiment, the first wire 8 is constituted of a so-called Cu wire a main composition of which is Cu. A wire with a main composition of Cu includes, for example, a wire constituted of a Cu single body (the purity of Cu is, for example, not less than 99.99%), a Cu alloy wire, Cu of which is alloyed with other alloy compositions, and a wire in which the Cu single body wire or the Cu alloy wire is covered by a conductive layer. An alloy composition of the Cu alloy wire includes, for example, Ag, Au, Al, Ni, Be, Fe, Ti, Pd, Zn, Sn, etc. Further, a covering composition of the Cu wire covered by the conductive layer includes, for example, Pd, etc. It is noted that an Au wire and an Al wire may be used as a modified example of the first wire 8. Where the Au wire is used as a bonding wire, it is unstable in cost because Au is high in cost and subject to price fluctuations. Further, a compound grows between gold and aluminum in a high-temperature environment and the wire debonding will easily occur. Further, where the Al wire is used as a bonding wire, aluminum is relatively low in melting point and undergoes recrystallization easily in a high-temperature environment. Use of the Cu wire as the first wire 8 makes it possible to provide a semiconductor device higher in reliability than a case where the Au wire and the Al wire are used. Where the first wire 8 is, for example, the Cu wire, it may have a diameter of not less than 18 μm and not more than 50 μm.

The first wire 8 connects the first pad 7 and the first pad portion 221 of the first lead portion 22. The first wire 8 may include a long wire 81 and a short wire 82 shorter than the long wire 81. The long wire 81 may be connected to a first pad 7 of the mutually adjacent pair of first pads 7 at a side far from the first lead portion 22. On the other hand, the short wire 82 may be connected to a first pad 7 of the pair of first pads 7 at a side close to the first lead portion 22.

The long wire 81 and the short wire 82 may be each provided in a plural number and disposed alternately along a longitudinal direction of the first pad portion 221. Further, a bonding portion 811 at the first pad portion 221 side of the long wire 81 and a bonding portion 821 at the first pad portion 221 side of the short wire 82 are each disposed so as to deviate to one side and the other side in relation to a width direction intersecting the longitudinal direction of the first pad portion 221. Thereby, the bonding portion 811 of the long wire 81 and the bonding portion 821 of the short wire 82 are disposed so as to deviate to each other, by which they can be prevented from being in contact with each other. As a result, it is possible to save space of the first lead portion 22.

The second conductive film 52 may include integrally a pad electrode portion 521 and a finger electrode portion 522. The pad electrode portion 521 is formed in the outer peripheral region 63 and, in the preferred embodiment, disposed at one corner of the semiconductor element 3. The finger electrode portion 522 is formed in the outer peripheral region 63 along a peripheral edge portion of the semiconductor element 3 from the pad electrode portion 521. In the preferred embodiment, the finger electrode portion 522 is formed along the first end surfaces 31A, 31B and the second end surfaces 32A, 32B of the semiconductor element 3 so as to surround the first conductive film 51. Further, the finger electrode portion 522 may be formed in the clearance region 61 between the mutually adjacent first conductive films 51. Thereby, each of the first conductive films 51 is individually surrounded by the finger electrode portion 522.

The finger electrode portion 522 is covered by the insulating film 6. On the other hand, a part of the pad electrode portion 521 is exposed from the insulating film 6 as a second pad 9.

The second wire 10 is connected to the second pad 9. The second wire 10 may be made of the same material as the first wire 8. That is, in the preferred embodiment, the second wire 10 may be constituted of a so-called Cu wire a main composition of which is Cu. However, as a modified example, an Au wire and an Al wire may be used. Further, the second wire 10 may have the same diameter as the first wire 8. That is, for example, in the case of a Cu wire, the second wire 10 may have a diameter of not less than 18 μm and not more than 50 μm.

The second wire 10 connects the second pad 9 and the second pad portion 231 of the second lead portion 23. The second wire 10 may have a length shorter than the short wire 82 of the first wire 8.

The third conductive film 53 is formed in the outer peripheral region 63 along the peripheral edge portion of the semiconductor element 3 further outside than the second conductive film 52. In the preferred embodiment, the third conductive film 53 is formed in a closed annular shape along the first end surfaces 31A, 31B and the second end surfaces 32A, 32B of the semiconductor element 3 so as to surround the second conductive film 52.

The package 4 partially covers the semiconductor element 3, the first wire 8, the second wire 10 and the lead frame 2 and may be referred to as a sealing resin. The package 4 is constituted of an insulative material. In the preferred embodiment, the package 4 is, for example, constituted of a black epoxy resin.

### [Structure of Active Region 64]

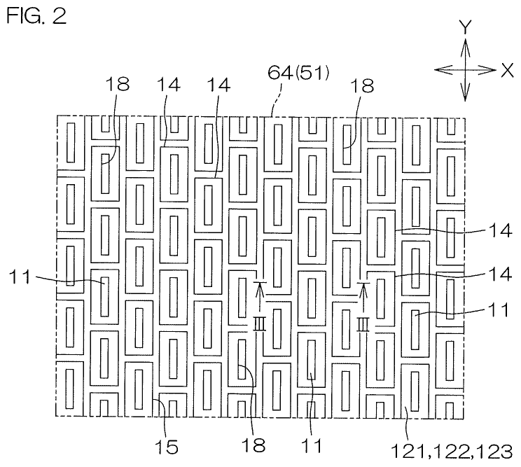

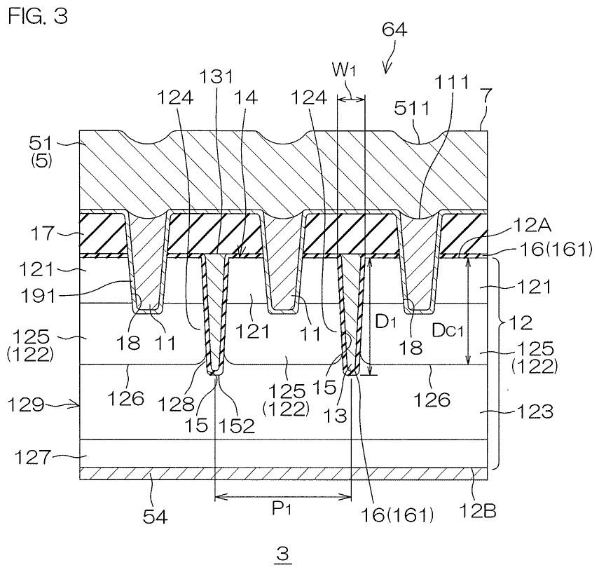

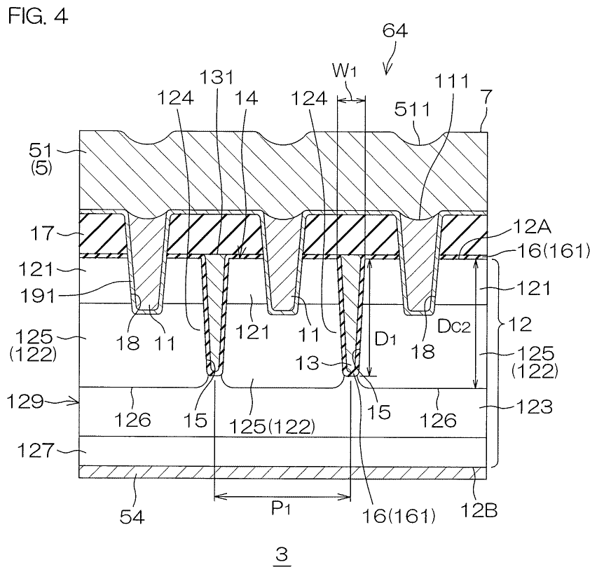

FIG. 2 is a partially enlarged view which shows a planar structure of the active region 64 in FIG. 1. FIG. 3 and FIG. 4 are each a view which shows a cross section III-III in FIG. 2 and respectively show the first mode and the second mode of a second impurity region 122.

The semiconductor device 1 is provided with a semiconductor chip 12, a first impurity region 121 (source), a second impurity region 122 (body), a third impurity region 123 (drain), a gate trench 15 (cell trench), a gate insulating film 16, a gate electrode 13 (control electrode), an interlayer insulating film 17, a source contact 18 and a first contact plug 11.

The semiconductor chip 12 constitutes an outer shape of the semiconductor element 3 and is, for example, a structure body in which a single-crystalline semiconductor material is formed in a chip shape (rectangular parallelepiped shape). The semiconductor chip 12 is made of a semiconductor material such as Si, SiC, etc. The semiconductor chip 12 has a first principal surface 12A and a second principal surface 12B at the opposite side of the first principal surface 12A. The first principal surface 12A is a device surface in which a functional device is formed. The second principal surface 12B is a non-device surface in which no functional device is formed. In the preferred embodiment, the semiconductor chip 12 may include a semiconductor substrate 127 and an epitaxial layer 129.

The semiconductor substrate 127 supports the epitaxial layer 129. The semiconductor substrate 127 may be a p-type impurity region which is formed at a surface layer portion of the second principal surface 12B of the semiconductor chip 12. A thickness of the semiconductor substrate 127 may be, for example, not less than 50 μm and not more than 300 μm. A p-type impurity concentration of the semiconductor substrate 127 may be not less than 1×10¹⁸ cm⁻³ and not more than 1×10²⁰ cm⁻³.

As shown in FIG. 3 and FIG. 4, the first impurity region 121 is a p-type impurity region which is selectively formed at a surface layer portion of the first principal surface 12A of the semiconductor chip 12 below the first conductive film 51. A p-type impurity concentration of the first impurity region 121 may be not less than 1×10¹⁸ cm⁻³ and not more than 1×10²⁰ cm⁻³. Further, in the preferred embodiment, the first impurity region 121 may be referred to as a p-type source region.

The second impurity region 122 is an n-type impurity region which is formed at the surface layer portion of the first principal surface 12A of the semiconductor chip 12. In the active region 64, the second impurity region 122 is formed so as to be in contact with the first impurity region 121 at an interval at the second principal surface 12B side from the first principal surface 12A. That is, the second impurity region 122 faces the first principal surface 12A across the first impurity region 121. An n-type impurity concentration of the second impurity region 122 may be not less than 1×10¹⁵ cm⁻³ and not more than 1×10¹⁹ cm⁻³. Further, the second impurity region 122 is a region in which a channel is formed in the active region 64 and, therefore, may be referred to as an n-type channel region 125. In other words, the channel region 125 may be referred to as a body region.

The channel region 125 may include a side portion 124 which forms a side surface of the gate trench 15 and a convex bottom portion 126 which is curved outward to the second principal surface 12B side so as to separate from the side surface of the gate trench 15 from a lower end of the side portion 124. As shown in FIG. 3, the bottom portion 126 of the channel region 125 may face the gate trench 15 across a clearance 128 which is constituted of a part of the third impurity region 123. That is, the bottom portion 126 of the channel region 125 may be positioned at the first principal surface 12A side from a lower end 152 of the gate trench 15. On the other hand, as shown in FIG. 4, the bottom portion 126 of the channel region 125 may be positioned further at the second principal surface 12B side than the lower end 152 of the gate trench 15. In this case, the bottom portion 126 of the channel region 125 may protrude further to the second principal surface 12B side than the lower end 152 of the gate trench 15.

The third impurity region 123 is a p-type impurity region which is formed at the surface layer portion of the first principal surface 12A of the semiconductor chip 12. The third impurity region 123 is formed so as to be in contact with the channel region 125. The third impurity region 123 may have a specific resistance of not less than 3.5 Ω·cm and not more than 4.5 Ω·cm. Thereby, the semiconductor device 1 may have a withstand voltage of not less than 100V. Here, the “withstand voltage” may be, for example, defined as a maximum voltage applicable in a range that the semiconductor element 3 does not undergo breakdown between a source and a drain (between first conductive film 51 and fourth conductive film 54) in an off state that no voltage is applied to the gate electrode 13.

The third impurity region 123 may be constituted of the epitaxial layer 129. A p-type impurity concentration of the third impurity region 123 is lower than p-type impurity concentrations of the semiconductor substrate 127 and the first impurity region 121 and, for example, may be not less than 1×10¹⁵ cm⁻³ and not more than 1×10¹⁸ cm⁻³. A thickness of the third impurity region 123 (epitaxial layer 129) may be not less than 1 μm and not more than 500 μm. Further, in the preferred embodiment, the third impurity region 123 may be referred to as a p-type drift region or a p-type drain region.

The gate trench 15 is a recessed portion which penetrates through the first impurity region 121 and the channel region 125 to reach the third impurity region 123. As shown in FIG. 2, the gate trench 15 surrounds the first impurity region 121, the channel region 125 and the third impurity region 123 and thereby demarcates a transistor cell 14 (semiconductor element structure) which includes the regions 121, 122, 123. In the preferred embodiment, as shown in FIG. 2, the transistor cell 14 is selectively formed in a region below the first conductive film 51. That is, the transistor cell 14 is covered by the first conductive film 51 but not covered by the second conductive film 52 or the third conductive film 53.

In FIG. 2, an arrayed pattern of the transistor cells 14 is in a zigzag shape. Although not shown, the arrayed pattern of the transistor cells 14 may be in a matrix shape or in a stripe shape. Each of the transistor cells 14 is formed in a quadrilateral shape in a plan view, as shown in FIG. 2 and, in the preferred embodiment, formed in a rectangular shape.

The gate trench 15 is formed between the plurality of transistor cells 14 arrayed as above. The gate trench 15 is formed in a tapered shape in which an opening width W₁ is gradually narrowed toward a depth direction of the gate trench 15. The width W₁ of the gate trench 15 may be, for example, not less than 0.17 μm and not more than 0.22 μm at an opening end of the gate trench 15. Further, as shown in FIG. 3 and FIG. 4, a pitch P₁ of mutually adjacent gate trenches 15 is, for example, not more than 1 μm. As shown in FIG. 2, where the gate trenches 15 continue so as to surround each of the plurality of transistor cells 14, the pitch P₁ of gate trenches 15 may be, for example, a distance between the gate trenches 15 which face each other across one transistor cell 14. Further, a depth D₁ of the gate trench 15 may be, for example, not less than 0.8 μm and not more than 1.2 μm.

As shown in FIG. 3 and FIG. 4, the gate insulating film 16 covers an inner surface of the gate trench 15. The gate insulating film 16 also covers the first principal surface 12A of the semiconductor chip 12. The gate insulating film 16 is made of an insulating material which contains, for example, SiO₂, SiN, etc. Of the gate insulating film 16 in its entirety, a portion formed in the active region 64 and a portion formed at an inner surface of the trench 15 may be referred to as a first insulating film 161 of the gate insulating film 16 in order to be distinguished from a second insulating film 162 or a third insulating film 163 to be described later.

The gate electrode 13 is housed (embedded) in the gate trench 15. This structure makes it possible to realize miniaturization and low on-resistance, as compared with a planar structure. Further, the gate electrode 13 is insulated by the gate insulating film 16 from the semiconductor chip 12, thereby preventing a leakage current. The gate electrode 13 is a conductive material which contains polysilicon, etc. Since polysilicon is substantially equal in melting point to monocrystalline silicon, use of polysilicon as the gate electrode 13 eliminates a process restriction by a temperature in a process subsequent to formation of the gate electrode 13.

The gate electrode 13 faces the channel region 125 via the gate insulating film 16. In the channel region 125, the side portion 124 which faces the gate electrode 13 is a channel portion. A voltage is applied to the gate electrode 13, by which a carrier (electron in the preferred embodiment) is induced at the side portion 124 of the channel region 125 and a channel is formed, resulting in conduction between the first impurity region 121 and the third impurity region 123. That is, in the semiconductor device 1, the transistor cell 14 and the gate electrode 13 constitute a vertical-type element structure in which a current flows in a thickness direction of the semiconductor chip 12.

As shown in FIG. 3 and FIG. 4, the gate electrode 13 may have an upper surface 131 which is flush with the first principal surface 12A of the semiconductor chip 12 or recessed to the second principal surface 12B side. On the first principal surface 12A of the semiconductor chip 12, the interlayer insulating film 17 is formed so as to cover the gate insulating film 16 and the gate electrode 13. The interlayer insulating film 17 insulates the gate electrode 13 from the first conductive film 51. Therefore, the gate electrode 13 is constituted so as to be covered by the gate insulating film 16 and the interlayer insulating film 17. The interlayer insulating film 17 is an insulating material which contains SiO₂, SiN, etc.

With reference to FIG. 2 to FIG. 4, the source contact 18 is formed at each transistor cell 14. In the preferred embodiment, although one source contact 18 is formed at each transistor cell 14, it may be formed in a plural number at each transistor cell 14. The source contact 18 is formed in a rectangular shape in a plan view which is long along a longitudinal direction of the rectangular-shaped transistor cell 14 in a plan view.

With reference to FIG. 3 and FIG. 4, the source contact 18 is a recessed portion which penetrates through the interlayer insulating film 17, the gate insulating film 16 and the first impurity region 121 and reaches the channel region 125. The source contact 18 is formed in a tapered shape in which an opening width thereof is gradually narrowed toward a depth direction of the source contact 18. Further, a pitch of mutually adjacent source contacts 18 is equal to the pitch P₁ of the gate trenches 15 and is, for example, not more than 1 μm.

The first contact plug 11 is embedded in the source contact 18 via a first barrier film 191. This constitution makes it possible to provide the semiconductor device 1 which mitigates an electric field concentration at a bottom portion of the gate trench 15 and improves the reliability.

The first barrier film 191 prevents a material which forms the first contact plug 11 from diffusing into the interlayer insulating film 17. In the preferred embodiment, the first contact plug 11 may contain W (tungsten) and the first barrier film 191 may contain a material which contains Ti (for example, single layer structure of Ti or laminated structure of Ti and TiN). A thickness of the first barrier film 191 is, for example, not less than 500 Å and not more than 800 Å.

The first barrier film 191 is formed so that one surface and the other surface will follow an inner surface of the source contact 18 and an upper surface of the interlayer insulating film 17 and is in direct conduction with the first impurity region 121 and the channel region 125. Further, the first barrier film 191 continues by crossing an upper region of the gate trench 15 which is a boundary of mutually adjacent transistor cells 14.

The first contact plug 11 is in conduction with the first impurity region 121 and the channel region 125 via the first barrier film 191. The first contact plug 11 has an upper surface 111 which is recessed at the first principal surface 12A side of the semiconductor chip 12 in relation to the upper surface of the interlayer insulating film 17.

The first conductive film 51 is formed on the interlayer insulating film 17. The first conductive film 51 may be referred to as a source electrode film on the basis of an electrical connection target thereof. The first conductive film 51 is in conduction with the first impurity region 121 and the channel region 125 via the first contact plug 11 and the first barrier film 191. The first conductive film 51 is constituted of a material which contains, for example, Al and, in the preferred embodiment, is constituted of AlCu.

As described above, the upper surface 111 of the first contact plug 11 is recessed to the upper surface of the interlayer insulating film 17. Consequently, in the upper surface of the first conductive film 51, a recessed portion 511 may be formed at a position which faces the upper surface 111 in a direction at which the first conductive film 51 is laminated.

A fourth conductive film 54 which is connected to the third impurity region 123 is formed in the second principal surface 12B of the semiconductor chip 12. The fourth conductive film 54 is a common electrode to all the transistor cells 14 and may be referred to as a drain electrode layer.

### [Structure of Outer Peripheral Region 63]

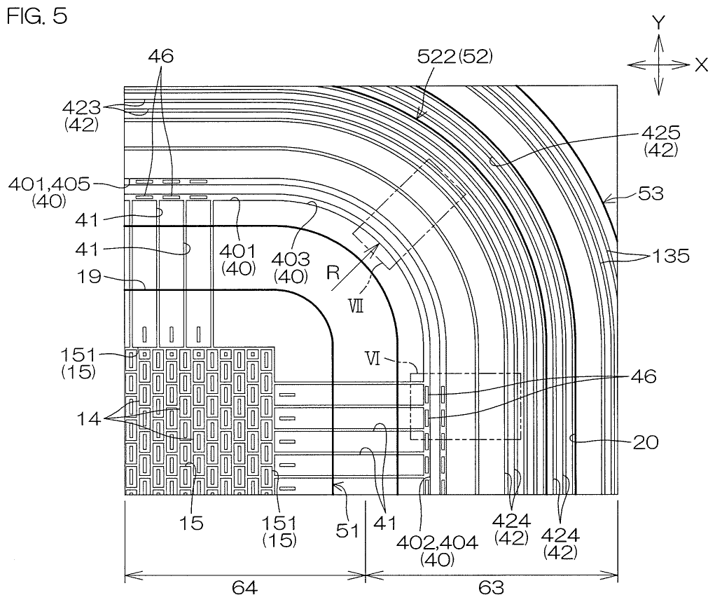

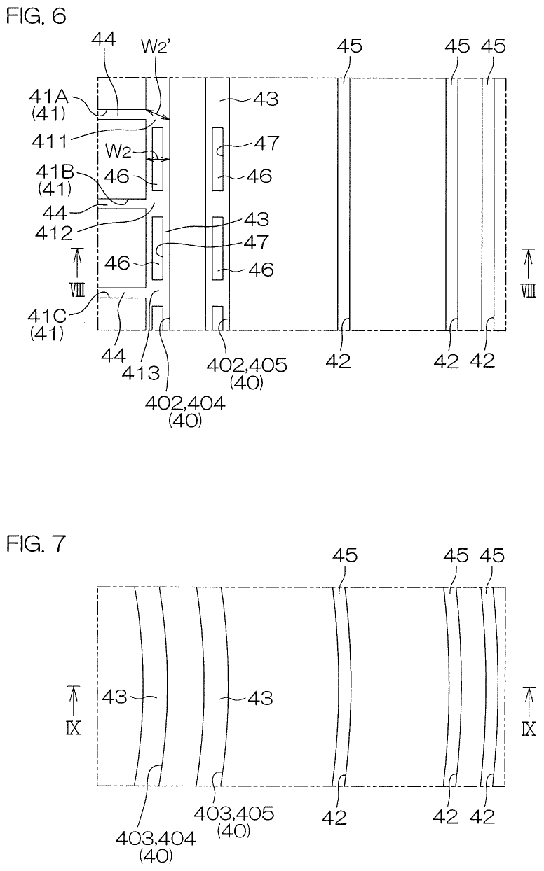

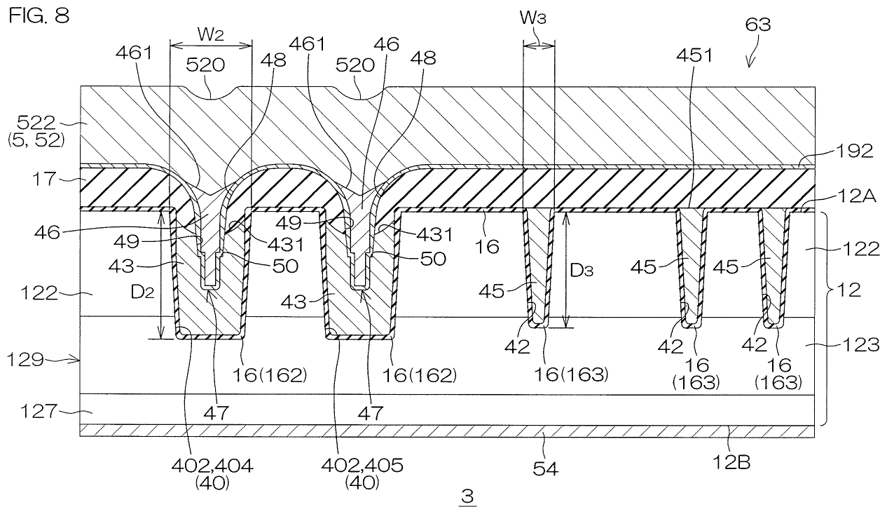

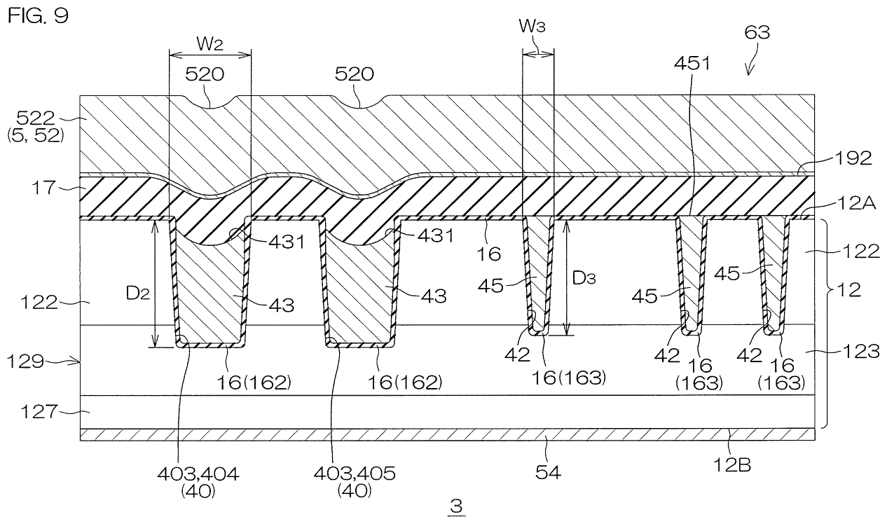

FIG. 5 is a view which shows a planar structure of the outer peripheral region 63 in FIG. 1 and an enlarged view which shows a corner of the semiconductor element 3 in FIG. 1. FIG. 6 is an enlarged view which shows a portion surrounded by a double dot & dashed line VI in FIG. 5. FIG. 7 is an enlarged view of a portion which is surrounded by a double dot & dashed line VII in FIG. 5. FIG. 8 is a view which shows a cross section VIII-VIII in FIG. 6. FIG. 9 is a view which shows a cross section IX-IX in FIG. 7.

First, with reference to FIG. 8 and FIG. 9, as an impurity region in the outer peripheral region 63, the semiconductor device 1 has the above-described second impurity region 122 and the third impurity region 123. The second impurity region 122 is exposed from the first principal surface 12A of the semiconductor chip 12.

In the outer peripheral region 63, the semiconductor device 1 is provided with a first outer peripheral trench 40, a connection trench 41, a second outer peripheral trench 42, a gate insulating film 16, a first embedded electrode 43, a connection electrode 44, a second embedded electrode 45 and a second contact plug 46.

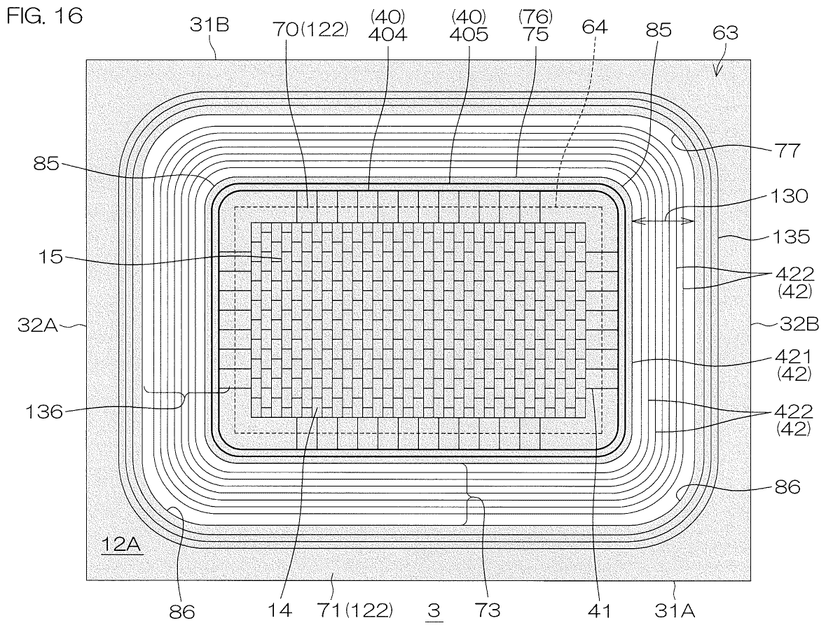

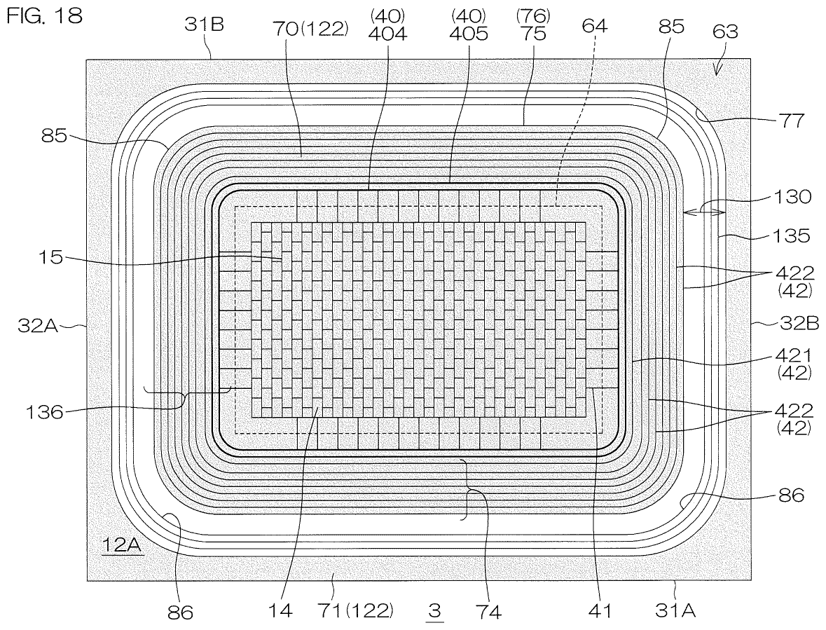

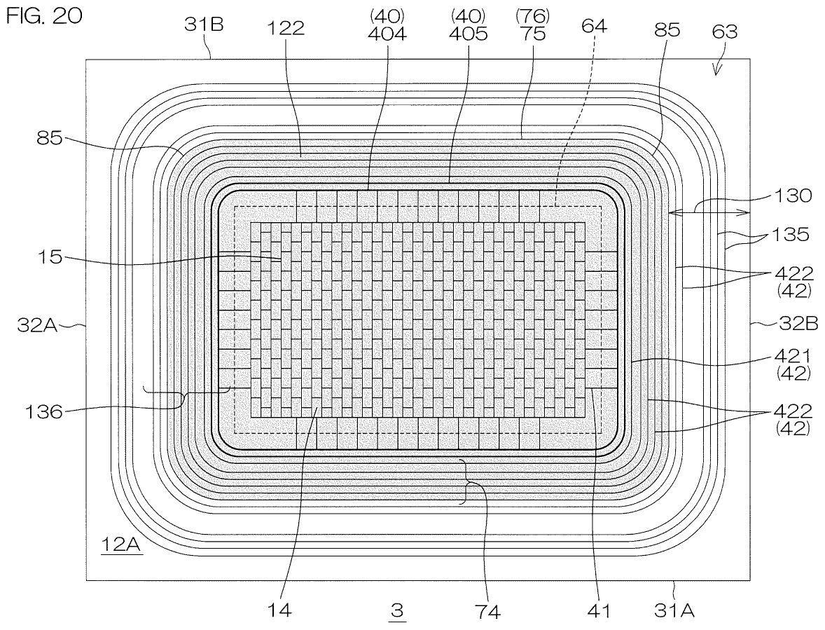

The first outer peripheral trench 40 is a recessed portion which penetrates through the second impurity region 122 and reaches the third impurity region 123. The first outer peripheral trench 40 is formed in an annular shape which surrounds an assembly of the transistor cells 14 formed in the active region 64 (refer also to FIG. 11, FIG. 16, FIG. 18 and FIG. 20). The first outer peripheral trench 40 is covered by the second conductive film 52 (finger electrode portion 522).

With reference to FIG. 8 and FIG. 9, the first outer peripheral trench 40 is formed in a tapered shape in which an opening width W₂ is gradually narrowed toward a depth direction of the first outer peripheral trench 40. The width W₂ of the first outer peripheral trench 40 is larger than the width W₁ of the gate trench 15 and may be, for example, not less than 0.5 μm and not more than 1.0 μm at an opening end of the first outer peripheral trench 40. Further, a depth D₂ of the first outer peripheral trench 40 is larger than the depth D₁ of the gate trench 15 and may be, for example, not less than 1.0 μm and not more than 1.4 μm.

With reference to FIG. 5, the first outer peripheral trench 40 includes a first linear portion 401 extending along the first direction X, a second linear portion 402 extending along the second direction Y and a corner portion 403 which connects the first linear portion 401 and the second linear portion 402. That is, in the preferred embodiment, the first outer peripheral trench 40 may be formed in a quadrilateral annular shape in a plan view. The corner portion 403 may be an intersecting portion of the first linear portion 401 with the second linear portion 402. The corner portion 403 has a shape which is curved so as to assume a protrusion toward the outside of the outer peripheral region 63. For example, the corner portion 403 may be curved so as to have a predetermined curvature radius R (for example, not less than 15 μm and not more than 50 μm).

The connection trench 41 is a recessed portion which connects the gate trench 15 and the first outer peripheral trench 40. The connection trench 41 is formed so as to stretch between the active region 64 and the outer peripheral region 63 (refer also to FIG. 11, FIG. 16, FIG. 18 and FIG. 20). In other words, the connection trench 41 crosses a boundary portion between the active region 64 and the outer peripheral region 63 (for example, as shown in FIG. 5, a clearance region 19 between the first conductive film 51 and the second conductive film 52). In the preferred embodiment, as shown in FIG. 5, the connection trench 41 extends from an annular external gate trench 151 which constitutes an outer periphery of the assembly of the transistor cells 14 along each in the first direction X and in the second direction Y and is connected to the first linear portion 401 and the second linear portion 402 of the first outer peripheral trench 40.

The connection trench 41 includes the plurality of connection trenches 41 in a stripe shape which are parallel to each other, and each of the connection trenches 41 may be connected at a different position of the first outer peripheral trench 40. For example, with reference to FIG. 6, the connection trench 41 may include a first connection trench 41A which is connected to the first outer peripheral trench 40 at a first connection site 411, a second connection trench 41B which is connected to the first outer peripheral trench 40 at a second connection site 412 and a third connection trench 41C which is connected to the first outer peripheral trench 40 at a third connection site 413. The first to third connection sites 411 to 413 may be respectively intersecting portions formed by the first outer peripheral trench 40 which intersects a first to third connection trenches 14A to 14C in a T-letter shape.

Here, the first outer peripheral trench 40 includes the plurality of first outer peripheral trenches 40. In the preferred embodiment, the first outer peripheral trench 40 may include an inner trench 404 and an outer trench 405. As shown in FIG. 5 and FIG. 6, the inner trench 404 surrounds the assembly of the transistor cells 14 formed in the active region 64 and is physically connected to the connection trench 41 (refer also to FIG. 11, FIG. 16, FIG. 18 and FIG. 20). Of the inner trench 404 and the outer trench 405, the connection trench 41 is communicatively connected selectively to the inner trench 404 but not communicatively connected to the outer trench 405. The outer trench 405 is in an annular shape which surrounds the inner trench 404 and formed outside at an interval from the inner trench 404 and physically independent from the inner trench 404 (refer also to FIG. 11, FIG. 16, FIG. 18 and FIG. 20).

The second outer peripheral trench 42 is a recessed portion which penetrates through the second impurity region 122 and reaches the third impurity region 123. The second outer peripheral trench 42 is formed physically independent from the first outer peripheral trench 40 further outside than the first outer peripheral trench 40 and formed in an annular shape which surrounds the assembly of the transistor cells 14 formed in the active region 64 (refer also to FIG. 11, FIG. 16, FIG. 18 and FIG. 20). In the preferred embodiment, the second outer peripheral trench 42 faces the first outer peripheral trench 40 (outer trench 405 in the preferred embodiment) across the second impurity region 122. With reference to FIG. 5, the plurality of second outer peripheral trenches 42 are formed. The plurality of second outer peripheral trenches 42 may be referred to as the second outer peripheral trench group 42. Some of the plurality of second outer peripheral trenches 42 may be covered (overlapped) by the second conductive film 52 (finger electrode portion 522) in a plan view, and the rest of the plurality of second outer peripheral trenches 42 may be formed at a boundary portion between the second conductive film 52 and the third conductive film 53 (for example, a clearance region 20 between the second conductive film 52 and the third conductive film 53, as shown in FIG. 5) and surrounds the second conductive film 52.

With reference to FIG. 8 and FIG. 9, the second outer peripheral trench 42 is formed in a tapered shape in which an opening width W₃ is gradually narrowed toward a depth direction of the second outer peripheral trench 42. The width W₃ of the second outer peripheral trench 42 is larger than the width W₁ of the gate trench 15 and smaller than the width W₂ of the first outer peripheral trench 40. The width W₃ of the second outer peripheral trench 42 may be, for example, not less than 0.23 μm and not more than 0.28 μm at an opening end of the second outer peripheral trench 42. A depth D₃ of the second outer peripheral trench 42 is smaller than the depth D₂ of the first outer peripheral trench 40 and may be, for example, not less than 0.8 μm and not more than 1.2 μm.

With reference to FIG. 5, the second outer peripheral trench 42 may be in a quadrilateral annular shape formed along the first outer peripheral trench 40 in a plan view. The second outer peripheral trench 42 includes a first linear portion 423 extending along the first direction X, a second linear portion 424 extending along the second direction Y and a corner portion 425 which connects the first linear portion 423 and the second linear portion 424. That is, in the preferred embodiment, the second outer peripheral trench 42 may be formed in a quadrilateral annular shape in a plan view. The corner portion 425 may be an intersecting portion of the first linear portion 423 with the second linear portion 424. The corner portion 425 has a curved shape so as to assume a protrusion toward the outside of the outer peripheral region 63.

With reference to FIG. 8 and FIG. 9, in the outer peripheral region 63, the gate insulating film 16 covers an inner surface of the first outer peripheral trench 40 and an inner surface of the second outer peripheral trench 42 and also covers the first principal surface 12A of the semiconductor chip 12. Of the gate insulating film 16 in its entirety, a portion formed in the inner surface of the first outer peripheral trench 40 and a portion formed in the inner surface of the second outer peripheral trench 42 may be respectively referred to as a second insulating film 162 and a third insulating film 163. That is, in the preferred embodiment, the first insulating film 161 which is formed in the active region 64, the second insulating film 162 which is formed in the outer peripheral region 63 and the third insulating film 163 are formed integrally via the gate insulating film 16 on the first principal surface 12A. Further, although not shown, the inner surface of the connection trench 41 is also covered by the gate insulating film 16.

The first embedded electrode 43 is housed (embedded) in the first outer peripheral trench 40. The first embedded electrode 43 may be made of the same material as the gate electrode 13. That is, the first embedded electrode 43 is a conductive material which contains polysilicon, etc. Since polysilicon is substantially equal in melting point to monocrystalline silicon, polysilicon is used as the first embedded electrode 43, thereby eliminating a process restriction by a temperature in a process subsequent to formation of the first embedded electrode 43. The first embedded electrode 43 faces the second impurity region 122 via the second insulating film 162. As shown in FIG. 8 and FIG. 9, the first embedded electrode 43 may have an upper surface 431 which is recessed to the second principal surface 12B side in relation to the first principal surface 12A of the semiconductor chip 12.

With reference to FIG. 6, the connection electrode 44 is housed (embedded) in the connection trench 41. The connection electrode 44 may be made of the same material as the gate electrode 13. That is, the connection electrode 44 is a conductive material which contains polysilicon, etc. Since polysilicon is substantially equal in melting point to monocrystalline silicon, polysilicon is used as the connection electrode 44, thereby eliminating a process restriction by a temperature in a process subsequent to formation of the connection electrode 44. Although not shown, as with the first embedded electrode 43, the connection electrode 44 faces the second impurity region 122 via the gate insulating film 16 formed in an inner surface of the connection trench 41. The connection electrode 44 is integrally formed with the gate electrode 13 and the first embedded electrode 43 inside the inner trench 404, thereby electrically connecting the gate electrode 13 and the first embedded electrode 43.

The second embedded electrode 45 is housed (embedded) in the second outer peripheral trench 42. The second embedded electrode 45 may be made of the same material as the gate electrode 13. That is, the second embedded electrode 45 is a conductive material which contains polysilicon, etc. Since polysilicon is substantially equal in melting point to monocrystalline silicon, polysilicon is used as the second embedded electrode 45, thereby eliminating a process restriction by a temperature in a process subsequent to formation of the second embedded electrode 45. The second embedded electrode 45 faces the second impurity region 122 via the third insulating film 163. The second embedded electrode 45 is electrically separated from the gate electrode 13 and the first embedded electrode 43 and, in the preferred embodiment, is an electrically floating electrode. As shown in FIG. 8 and FIG. 9, the second embedded electrode 45 may have an upper surface 451 which is flush with the first principal surface 12A of the semiconductor chip 12 or recessed to the second principal surface 12B side.

The interlayer insulating film 17 is formed so as to cover the gate insulating film 16, the first embedded electrode 43, the connection electrode 44 and the second embedded electrode 45. The interlayer insulating film 17 insulates the first embedded electrode 43, the connection electrode 44 and the second embedded electrode 45 from the second conductive film 52.

A contact hole 47 is formed in the interlayer insulating film 17. The contact hole 47 reaches an intermediate portion of the first embedded electrode 43 in a depth direction of the first outer peripheral trench 40. Therefore, side surfaces of the contact hole 47 may include a first side surface 48 (upper side surface) constituted of an insulative region formed by the interlayer insulating film 17 and a second side surface 49 (lower side surface) constituted of a conductive region formed by the first embedded electrode 43. Further, a step 50 may be formed in the second side surface 49 of the contact hole 47 so that a width of the contact hole 47 will be narrowed in a stepwise manner inside the first embedded electrode 43.

The contact hole 47 is formed at the first linear portion 401 and the second linear portion 402 of the first outer peripheral trench 40. Here, although a structure of the contact hole 47 formed at the second linear portion 402 will be described with reference to FIG. 6, the following description is also applicable to the first linear portion 401.

The contact hole 47 is formed at a position of the second linear portion 402 in which a connection site of the connection trench 41 (first to third connection sites 411 to 413 in FIG. 6) is avoided. Specifically, the contact hole 47 is formed at a portion of the first outer peripheral trench 40 between the mutually adjacent connection sites 411 to 413. In the first to third connection sites 411 to 413, a side surface of the first outer peripheral trench 40 is replaced by the connection trench 41, thereby forming a portion which has a width W₂ wider than the width W₂ of the first outer peripheral trench 40. The wider the width of the trench is, the lower the embedding property of the embedded electrode (for example, polysilicon) becomes, and there is a concern that, after being embedded, a hollow defect which is called a porosity may occur. For example, in an example shown in FIG. 6, a defect can be found in the first embedded electrode 43 near the central portion of each of the first to third connection sites 411 to 413. Thus, the contact hole 47 is formed so as to avoid the first to third connection sites 411 to 413, by which the second contact plug 46 can be favorably connected to the first embedded electrode 43.

The second contact plug 46 is embedded in the contact hole 47 via a second barrier film 192. The second barrier film 192 prevents a material which forms the second contact plug 46 from diffusing in the interlayer insulating film 17. In the preferred embodiment, the second contact plug 46 may contain W (tungsten) and the second barrier film 192 may contain a material which contains Ti (for example, single layer structure of Ti or laminated structure of Ti and TiN). A thickness of the second barrier film 192 is, for example, not less than 500 Å and not more than 800 Å.

The second barrier film 192 has one surface and the other surface which are formed by following the inner surface of the contact hole 47 and the upper surface of the interlayer insulating film 17 and is in direct conduction with the first embedded electrode 43. The second contact plug 46 is in conduction with the first embedded electrode 43 via the second barrier film 192. The second contact plug 46 has an upper surface 461 which is recessed at the first principal surface 12A side of the semiconductor chip 12 in relation to the upper surface of the interlayer insulating film 17.

The second conductive film 52 is formed on the interlayer insulating film 17. The second conductive film 52 may be referred to as a gate electrode film on the basis of an electrical connection target thereof. The second conductive film 52 is in conduction with the gate electrode 13 via the second contact plug 46 and the second barrier film 192 as well as the first embedded electrode 43 and the connection electrode 44 inside the inner trench 404. The second conductive film 52 is constituted of a material which contains, for example, Al and, in the preferred embodiment, constituted of AlCu. It is noted that the first embedded electrode 43 inside the outer trench 405 is not physically connected to the connection electrode 44. However, the first embedded electrode 43 inside the outer trench 405 is electrically connected to the second conductive film 52 via the second contact plug 46 and, therefore, is to be electrically connected to the gate electrode 13 via the second conductive film 52 as well as the first embedded electrode 43 and the connection electrode 44 inside the inner trench 404. That is, the first embedded electrode 43 inside the inner trench 404 and the first embedded electrode 43 inside the outer trench 405 are both kept at a potential (gate potential) of the second conductive film 52.

As described above, the upper surface 461 of the second contact plug 46 is recessed in relation to the upper surface of the interlayer insulating film 17. Consequently, in the upper surface of the second conductive film 52, a recessed portion 520 may be formed at a position which faces the upper surface 461 in a direction in which the second conductive film 52 is laminated.

[Relationship between Depth of Channel Region 125 and Leakage Current]

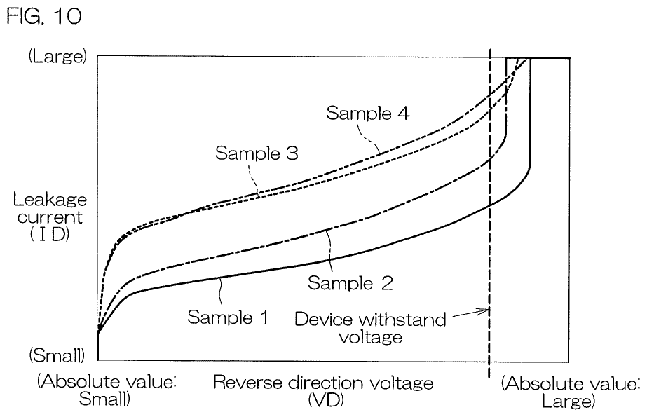

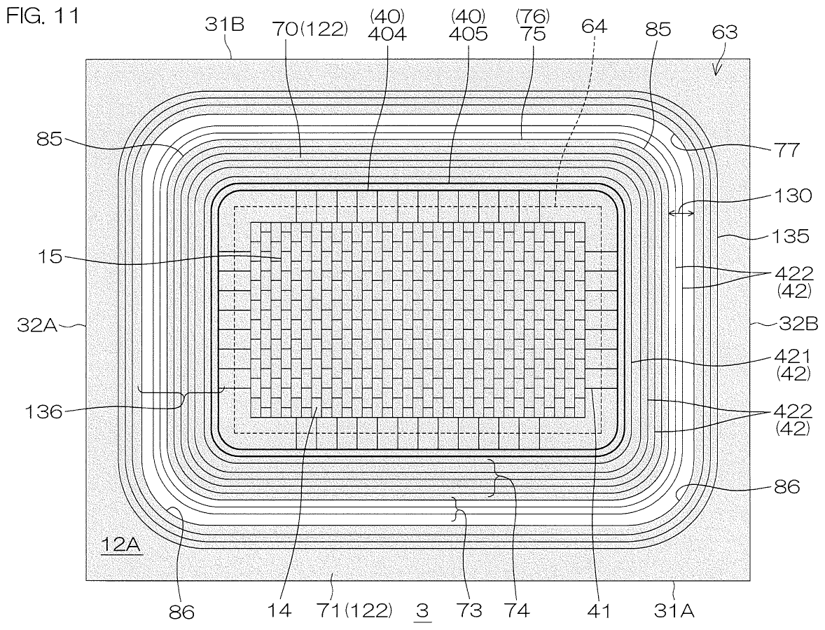

FIG. 10 is a view for comparing withstand voltages of the semiconductor devices according to Samples 1 to 4. In FIG. 10, the horizontal axis represents a magnitude of a reverse direction voltage (drain voltage VD) applied between a source and a drain and shows that the more the horizontal axis moves closer to the right side, the larger the absolute value of the reverse direction voltage becomes. In FIG. 10, the vertical axis represents a magnitude of a leakage current (drain current ID) when the reverse direction voltage is applied between the source and the drain, showing that the more the vertical axis moves closer to the upper side, the larger the leakage current becomes.

With reference to FIG. 10, a simulation is performed to check a change in leakage current in relation to a depth of the channel region 125. Specifically, a comparison is made for a leakage current of each of Samples 1 to 4 mutually different in depth of the channel region 125. In FIG. 3 and FIG. 4, the depth of the channel region 125 may be, for example, a depth D_{c1} (FIG. 3) and a depth D_{c2} (FIG. 4) from the first principal surface 12A of the semiconductor chip 12 to a lower end of the bottom portion 126 of the channel region 125. The depth of the channel region 125 can be controlled, for example, by changing an acceleration voltage of ion implantation when the second impurity region 122 is formed in the third impurity region 123 (epitaxial layer 129 to be described later) by ion implantation and thermal diffusion. Here, a specific resistance of the third impurity region 123 which is a target of ion implantation is not less than 3.5 Ω·cm and not more than 4.5 Ω·cm.

Sample 1 is designed to have a channel region 125 which is formed by subjecting the third impurity region 123 to implantation of an n-type impurity (P (phosphorus) in the preferred embodiment) at two steps of 180 keV and 70 keV and also to thermal diffusion. Sample 2 is designed to have a channel region 125 which is formed by subjecting the third impurity region 123 to implantation of an n-type impurity (P (phosphorus) in the preferred embodiment) at two steps of 180 keV and 140 keV and also to thermal diffusion. As shown in FIG. 3, the channel regions 125 of Samples 1 and 2 may have, for example, a bottom portion 126 which is positioned further at the first principal surface 12A side than the lower end 152 of the gate trench 15.

Sample 3 is designed to have a channel region 125 which is formed by subjecting the third impurity region 123 to implantation of an n-type impurity (P (phosphorus) in the preferred embodiment) at two steps of 280 keV and 140 keV and also to thermal diffusion. Sample 4 is designed to have a channel region 125 which is formed by subjecting the third impurity region 123 to an n-type impurity (P (phosphorus) in the preferred embodiment) at three steps of 280 keV, 140 keV and 70 keV and also to thermal diffusion. As shown in FIG. 4, the channel regions 125 of Sample 3 and 4 have, for example, a bottom portion 126 which is positioned further at the second principal surface 12B side than the lower end 152 of the gate trench 15.

With reference to FIG. 10, a comparison is made for leakage currents of Samples 1 to 4 to find that Sample 1 and 2 are smaller in leakage current than Sample 3 and 4 in an entire application range of the reverse direction voltage. Therefore, in view of reducing the leakage current, a depth position of the bottom portion 126 of the channel region 125 is preferably at the first principal surface 12A side (FIG. 3) rather than at the second principal surface 12B side (FIG. 4) in relation to the lower end 152 of the gate trench 15. In the preferred embodiment, in order to impart a withstand voltage of not less than 100V to the semiconductor device 1, a specific resistance of the third impurity region 123 is relatively high, that is, not less than 3.5 Ω·cm and not more than 4.5 Ω·cm. Consequently, the n-type impurity ion which has been subjected to ion implantation easily becomes wider in ion diffusion range, and the channel region 125 easily protrudes rather than the lower end 152 of the gate trench 15. Thus, as with Samples 1 and 2, an acceleration voltage at the time of ion implantation can be lowered and the leakage current can be reduced. That is, as a method for reducing the leakage current, there can be provided a low acceleration of acceleration voltage at the time of ion implantation in the second impurity region 122.

[Relationship Between Structure of Outer Peripheral Region 63 with Leakage Current and Device Withstand Voltage]

Next, a description will be given of an influence of a structure of the outer peripheral region 63 of the semiconductor element 3 on the leakage current and the device withstand voltage.

### <Effect on Reduction in Leakage Current by Formation of First Conductivity-Type Region 130 in Second Impurity Region 122>

Hereinafter, on the basis of Samples 5 to 11, a description will be given of a reduction in leakage current by forming the first conductivity-type region 130 in the second impurity region 122 of the outer peripheral region 63.

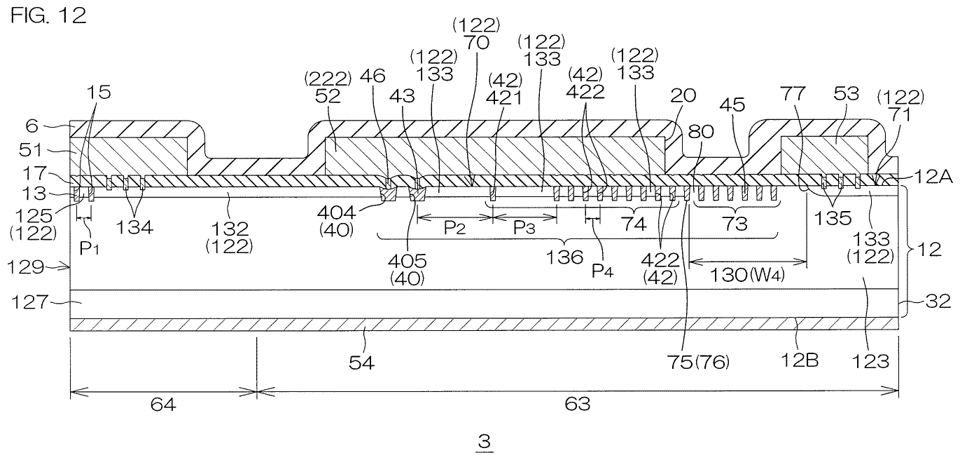

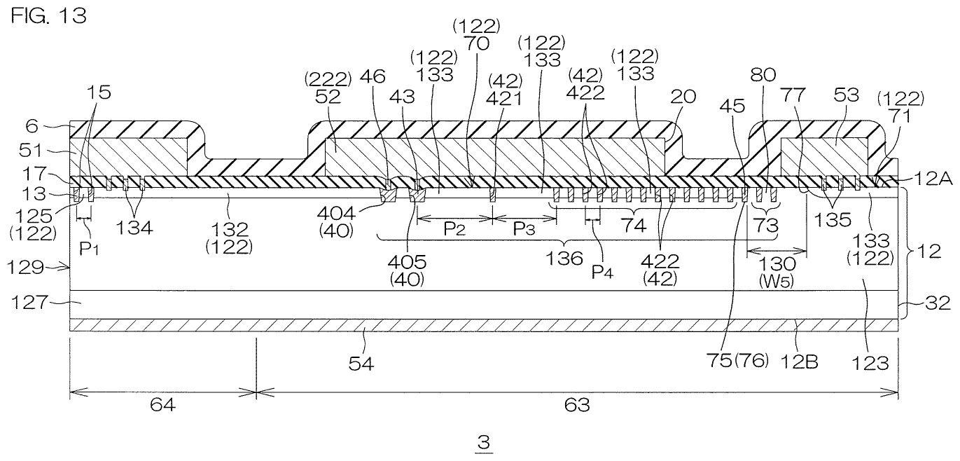

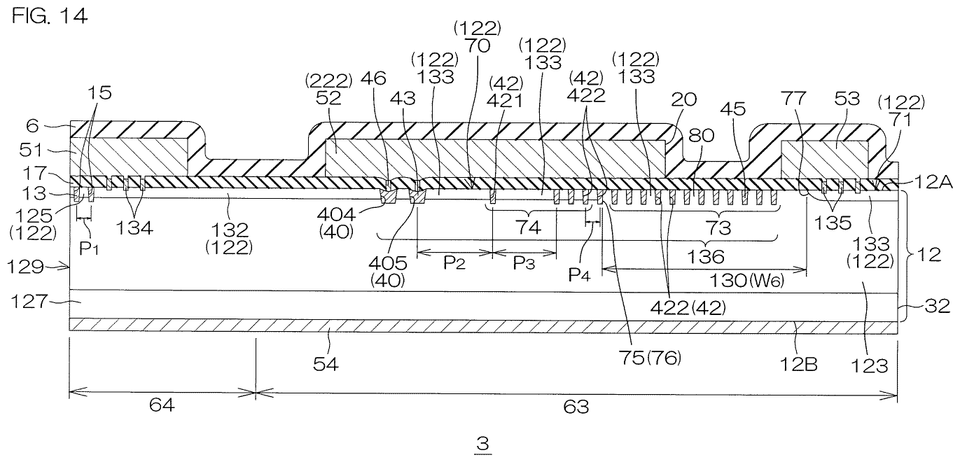

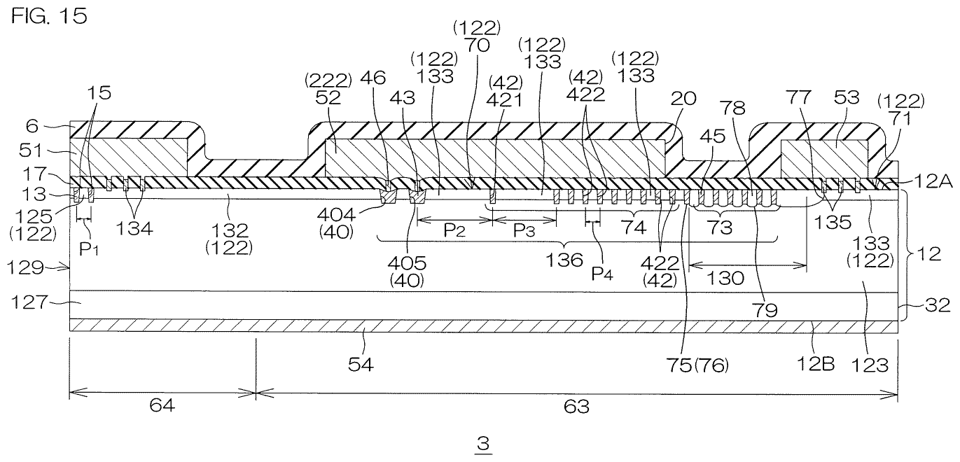

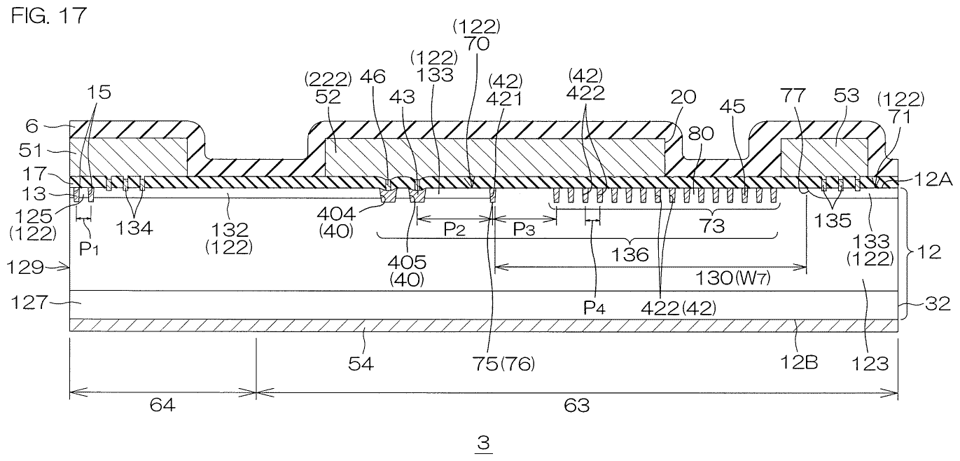

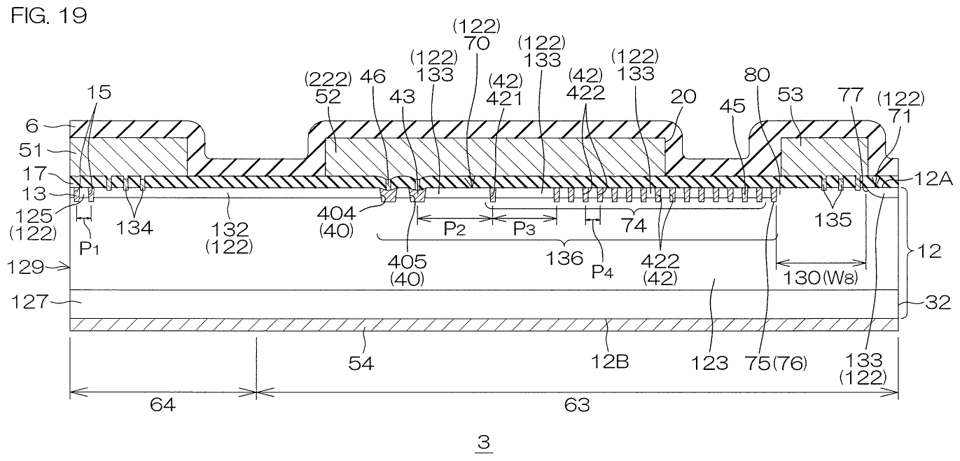

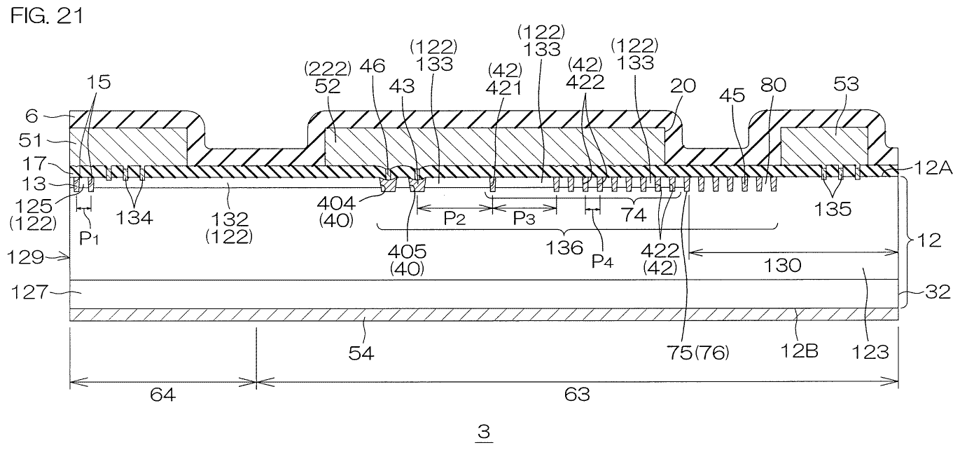

FIG. 11 is a schematic plan view of the semiconductor element 3 according to Samples 5 to 8. FIG. 12 is a schematic sectional view of the semiconductor element 3 according to Sample 5. FIG. 13 is a schematic sectional view of the semiconductor element 3 according to Sample 6. FIG. 14 is a schematic sectional view of the semiconductor element 3 according to Sample 7. FIG. 15 is a schematic sectional view of the semiconductor element 3 according to Sample 8. FIG. 16 is a schematic plan view of the semiconductor element 3 according to Sample 9. FIG. 17 is a schematic sectional view of the semiconductor element 3 according to Sample 9. FIG. 18 is a schematic plan view of the semiconductor element 3 according to Sample 10. FIG. 19 is a schematic sectional view of the semiconductor element 3 according to Sample 10. FIG. 20 is a schematic plan view of the semiconductor element 3 according to Sample 11. FIG. 21 is a schematic sectional view of the semiconductor element 3 according to Sample 11. In FIG. 11, FIG. 16, FIG. 18 and FIG. 20, description of a structure further above the first principal surface 12A of the semiconductor chip 12 is omitted.

In FIG. 11 to FIG. 21, a constitution necessary for describing an effect on reduction in the leakage current by formation of the first conductivity-type region 130 in the second impurity region 122 is selectively shown and, for example, the gate insulating film 16, etc., is omitted.

First, with regard to structures of the outer peripheral region 63 of the semiconductor element 3, a structure common to Samples 5 to 11 will be described with reference to FIG. 11 to FIG. 21.

As described above, the semiconductor chip 12 has the first principal surface 12A and the second principal surface 12B at the opposite side of the first principal surface 12A. In the outer peripheral region 63, the third impurity region 123 is formed at a surface layer portion of the semiconductor chip 12 at the first principal surface 12A side, and the second impurity region 122 is formed at a surface layer portion of the third impurity region 123.

As shown in FIG. 11, FIG. 16, FIG. 18 and FIG. 20, the second impurity region 122 is a well region which is continuously formed at an entire surface layer portion of the third impurity region 123 from the active region 64 toward the outer peripheral region 63. Here, an expression that the second impurity region 122 is continuously formed from the active region 64 toward outer peripheral region 63 means that the same conductivity-type of impurity region continues along a lateral direction following the first principal surface 12A of the semiconductor chip 12 from the channel region 125 of the active region 64. For example, the second impurity region 122 may be formed in an entire area of the first principal surface 12A excluding such portions that the first conductivity-type region 130, the first outer peripheral trench 40 and the second outer peripheral trench 42 are formed in a plan view.

The second impurity region 122 may include a first potential well region 132 and a floating region 133. The first potential well region 132 is formed in an inner region of the first outer peripheral trench 40. The first potential well region 132 is electrically connected to the first conductive film 51 via a third contact plug 134 formed on the interlayer insulating film 17 in the active region 64. Thereby, the first potential well region 132 is equal in potential to the first conductive film 51. In the preferred embodiment, the first potential well region 132 may be a source potential well region fixed at a source potential.

The floating region 133 is formed in an outer region of the first outer peripheral trench 40. The floating region 133 is physically separated by the first outer peripheral trench 40 from the first potential well region 132. Further, the floating region 133 is not connected to the first conductive film 51, the second conductive film 52 or the third conductive film 53 and is an electrically floating region.

The first conductivity-type region 130 is a region in which the second impurity region 122 is not selectively formed in the outer peripheral region 63 and exposed from the first principal surface 12A of the semiconductor chip 12. The first conductivity-type region 130 may be a region having a conductivity-type different from the second impurity region 122. For example, the second impurity region 122 may be defined as a first conductivity-type well region. In the preferred embodiment, the second impurity region 122 is of an n-type and the first conductivity-type region 130 is of a p-type.

The second outer peripheral trench 42 may include a first trench 421 and a second trench 422. The first trench 421 is a trench of the second outer peripheral trenches 42 which is adjacent to the first outer peripheral trench 40. The first trench 421 is formed at an interval of the first outer peripheral pitch P₂ from the first outer peripheral trench 40 at the first end surfaces 31A, 31B sides and the second end surfaces 32A, 32B sides of the semiconductor chip 12. Further, the first trench 421 faces the second conductive film 52 (finger electrode portion 522) across the interlayer insulating film 17.

The second trenches 422 are a plurality of trenches which are formed at an interval of a second outer peripheral pitch P₃ from the first trench 421 at the first end surfaces 31A, 31B sides and the second end surfaces 32A, 32B sides of the semiconductor chip 12. The second outer peripheral pitch P₃ may be a distance between the first trench 421 and the innermost second trench 422. The plurality of second trenches 422 are arrayed at an interval of a third outer peripheral pitch P₄ which is equal to each other. Some of the plurality of second trenches 422 face the second conductive film 52 (finger electrode portion 522) across the interlayer insulating film 17. The rest of the plurality of second trenches 422 face the clearance region 20 across the interlayer insulating film 17.

The third conductive film 53 is an outer peripheral electrode which is formed in the vicinity of the first end surfaces 31A, 31B and the second end surfaces 32A, 32B of the semiconductor chip 12. The third conductive film 53 is connected to the semiconductor chip 12 via an outer periphery contact plug 135 (outer periphery contact portion) formed in the interlayer insulating film 17. As shown in FIG. 11, FIG. 16, FIG. 18 and FIG. 20, the outer periphery contact plug 135 is formed in an annular shape which surrounds the second trench 422 in a plan view. In the preferred embodiment, the plurality of outer periphery contact plugs 135 are formed.

It is noted that in the preferred embodiment, a trench group 136 may be defined as a group which includes the first outer peripheral trench 40 and the second outer peripheral trench 42 which are annular trenches formed in the outer peripheral region 63. In FIG. 12 to FIG. 15, FIG. 17, FIG. 19 and FIG. 21, although the trench group 136 is shown so as to include all the first outer peripheral trenches 40 and the second outer peripheral trenches 42, it may selectively include some of the first outer peripheral trenches 40 and some of the second outer peripheral trenches 42 which continue along the first principal surface 12A.

Next, structures of the outer peripheral region 63 different from each other in Samples 5 to 8 will be described individually. First, Sample 5 will be described with reference to FIG. 11 and FIG. 12.

In Sample 5, as shown in FIG. 11, the first conductivity-type region 130 is formed in an annular shape which surrounds the active region 64. Thereby, in the outer peripheral region 63, the second impurity region 122 is divided into a first portion 70 and a second portion 71.

The first conductivity-type region 130 is formed by the third impurity region 123, a part of which is exposed from the first principal surface 12A of the semiconductor chip 12. Therefore, a p-type impurity concentration of the first conductivity-type region 130 may be the p-type impurity concentration of the third impurity region 123. The first conductivity-type region 130 may be a first conductivity-type (p-type in the preferred embodiment) impurity region 80 having a difference in concentration that is not more than a single digit with the third impurity region 123 in a thickness direction of the semiconductor chip 12. That is, although the first conductivity-type region 130 is the impurity region 80 which is constituted of a part of the third impurity region 123, there is a case that a difference in concentration which is not more than a single digit may be found with the third impurity region 123 at the second principal surface 12B side in relation to the second impurity region 122 due to influences of conditions for manufacturing the semiconductor element 3, etc. For example, while the p-type impurity concentration of the third impurity region 123 at the second principal surface 12B side is expressed by 10¹⁵ cm⁻³, a p-type impurity concentration of the impurity region 80 may be expressed by 1×10¹⁶ cm⁻³.

The first conductivity-type region 130 is formed so as to stretch between a region directly under the clearance region 20 and a region directly under the third conductive film 53. The first conductivity-type region 130 is formed in an annular shape along the first outer peripheral trench 40 and the second outer peripheral trench 42, includes internally some of the plurality of second outer peripheral trenches 42 selectively and also overlaps the second outer peripheral trench 42. More specifically, the first conductivity-type region 130 in an annular shape includes internally the same second outer peripheral trenches 42 in an entire circumference thereof. That is, the second outer peripheral trenches 42 included in the first conductivity-type region 130 are not pushed out from the first conductivity-type region 130 but completely housed inside the first conductivity-type region 130 in a plan view.

With reference to FIG. 11, the first portion 70 of the second impurity region 122 is formed in an island shape in an inner region surrounded by the first conductivity-type region 130, and the second portion 71 is formed in an annular shape in an outer region which surrounds the first conductivity-type region 130. A boundary portion (first boundary portion 75) between the first portion 70 and the first conductivity-type region 130 is formed in a region directly under the clearance region 20. The first boundary portion 75 may be formed halfway in a radial direction of the trench group 136 including the trenches 40, 42 which spread in an annular shape at an interval toward the first end surfaces 31A, 31B and the second end surfaces 32A, 32B of the semiconductor chip 12. On the other hand, a boundary portion (second boundary portion 77) between the first conductivity-type region 130 and the second portion 71 is formed further internally than a region which is directly under the third conductive film 53 and also a connection position of the outer periphery contact plug 135 in the semiconductor chip 12. The second portion 71 is formed so as to reach the first end surfaces 31A, 31B and the second end surfaces 32A, 32B of the semiconductor chip 12 from the second boundary portion 77. The second portion 71 of the second impurity region 122 is exposed in the first end surfaces 31A, 31B and the second end surfaces 32A, 32B of the semiconductor chip 12.

Of the plurality of second outer peripheral trenches 42, the plurality of second outer peripheral trenches 42 which are continuously arrayed toward the first end surfaces 31A, 31B and the second end surfaces 32A, 32B of the semiconductor chip 12 and formed in the first conductivity-type region 130 exposed from the first principal surface 12A may be defined as a first trench group 73. On the other hand, of the plurality of second outer peripheral trenches 42, the plurality of second outer peripheral trenches 42 which are arrayed continuously toward the first end surfaces 31A, 31B and the second end surfaces 32A, 32B and formed so as to penetrate through the second impurity region 122 from the first principal surface 12A and reach the third impurity region 123 may be defined as a second trench group 74. The first trench group 73 may be formed relatively externally, while the second trench group 74 may be formed relatively internally so as to be surrounded by the first trench group 73.

A side surface of the second outer peripheral trench 42 which belongs to the first trench group 73 is formed by the first conductivity-type region 130 (a part of the third impurity region 123 in Sample 5), and a side surface of the second outer peripheral trench 42 which belongs to the second trench group 74 is formed by the second impurity region 122.

Further, the second outer peripheral trench 42 which is positioned at a boundary between the first trench group 73 and the second trench group 74 and forms the first boundary portion 75 between the second impurity region 122 and the first conductivity-type region 130 may be a boundary trench 76. As for side surfaces of the boundary trench 76, one side (inner side, for example) in a cross sectional view is formed by the second impurity region 122, and the other side (outer side, for example) in a cross sectional view is formed by the first conductivity-type region 130. The boundary trench 76 (first boundary portion 75) is positioned in a region directly under the clearance region 20.

As shown in FIG. 11, since the first boundary portion 75 is the boundary trench 76 (second outer peripheral trench 42), as with the shape of the second outer peripheral trench 42, the first boundary portion 75 is formed in a quadrilateral annular shape having a corner portion 85 which is curved like an arc in a plan view. The second boundary portion 77 is also formed in a quadrilateral annular shape having a corner portion 86 which is curved like an arc in a plan view. Therefore, the first conductivity-type region 130 is formed in a quadrilateral annular shape in a plan view having the corner portions 85, 86 in which an inner peripheral edge and an outer peripheral are both curved like an arc. The corner portions of the first boundary portion 75 and the second boundary portion 77 are curved like an arc, thus making it possible to suppress a concentration of electric field at the corner portions of the boundary portions 75, 77.

Further, a width W₄ of the first conductivity-type region 130 held between the first portion 70 and the second portion 71 of the second impurity region 122 may be, for example, not less than 8 μm and not more than 15 μm (preferably, about 10 μm).

Then, in order to form the first conductivity-type region 130, for example, after growth of the epitaxial layer 129 on the semiconductor substrate 127, via a mask corresponding to a pattern of the first conductivity-type region 130, an n-type impurity may be implanted into the semiconductor chip 12 to cause thermal diffusion, thereby forming the second impurity region 122. The n-type impurity is not implanted into a portion of the semiconductor chip 12 covered by the mask, and there is formed the first conductivity-type region 130 which keeps the conductivity-type of the epitaxial layer 129 (third impurity region 123).

Next, with reference to FIG. 11 and FIG. 13, Sample 6 will be described.

Sample 6 has a width W₅ of the first conductivity-type region 130 narrower than the width W₄ of the first conductivity-type region 130 of Sample 5. The width W₅ may be, for example, not less than 3 μm and not more than 7 μm (preferably, about 6 μm). The other constitutions of Sample 6 are the same as Sample 5. In order to change the width W₄ of the first conductivity-type region 130 to the width W₅, a pattern (width) of the mask used in forming the second impurity region 122 may be changed.

Next, with reference to FIG. 11 and FIG. 14, Sample 7 will be a described.

Sample 7 has a width W₆ of the first conductivity-type region 130 which is wider than the width W₄ of the first conductivity-type region 130 of Sample 5. The width W₆ may be, for example, not less than 8 μm and not more than 15 μm (preferably, about 13 μm). The other constitutions of Sample 7 are the same as those of Sample 5. In order to change the width W₄ of the first conductivity-type region 130 to the width W₆, a pattern (width) of a mask used in forming the second impurity region 122 may be changed.

Next, with reference to FIG. 11 and FIG. 15, Sample 8 will be described.

In Sample 8, the first conductivity-type region 130 is formed by a high concentration impurity region 78 having an impurity concentration higher than the third impurity region 123. For example, while the p-type impurity concentration of the third impurity region 123 is not less than 1×10¹⁵ cm⁻³ and not more than 1×10¹⁸ cm⁻³, the p-type impurity concentration of the high concentration impurity region 78 may be not less than 1×10¹⁸ cm⁻³ and not more than 1×10 20 cm⁻³. The p-type impurity concentration of the high concentration impurity region 78 may be the same as the p-type impurity concentrations of the semiconductor substrate 127 and the first impurity region 121.

The high concentration impurity region 78 is selectively formed at the surface layer portion of the third impurity region 123. Further, as shown in FIG. 15, a depth of the high concentration impurity region 78 may be deeper than the second outer peripheral trench 42. Thereby, the high concentration impurity region 78 may have a bottom portion 79 which protrudes further to the second principal surface 12B side than a lower end of the second outer peripheral trench 42. The other constitutions of Sample 8 are the same as Sample 5.

In order to form the high concentration impurity region 78, for example, after growth of the epitaxial layer 129 on the semiconductor substrate 127, an n-type impurity is implanted into an entirety of the first principal surface 12A of the semiconductor chip 12 without using a mask to cause thermal diffusion, thereby forming the second impurity region 122. Next, via a mask having an opening corresponding to a pattern of the high concentration impurity region 78, a p-type impurity is implanted into the first principal surface 12A of the semiconductor chip 12 to cause thermal diffusion, thereby forming the high concentration impurity region 78.

Next, with reference to FIG. 16 and FIG. 17, Sample 9 will be described.

Sample 9 has a width W₇ of the first conductivity-type region 130 which is wider than the width W₄ of the first conductivity-type region 130 of Sample 5. The width W₇ may be, for example, not less than 20 μm and not more than 27 μm (preferably, about 27 μm). More specifically, in Sample 9, the first trench 421 forms the boundary trench 76. Therefore, the second impurity region 122 is divided into an inner first portion 70 and an outer second portion 71, with the first trench 421 given as a boundary. A position of the second boundary portion 77 may be the same as that in Sample 5. Thereby, an entirety of the second trench 422 (excluding the boundary trench 76) may be included in the first trench group 73 which is formed in the first conductivity-type region 130. The other constitutions of Sample 9 are the same as Sample 5. In order to change the width W₄ of the first conductivity-type region 130 to the width W₇, a pattern (width) of the mask used in forming the second impurity region 122 may be changed.

Next, with reference to FIG. 18 and FIG. 19, Sample 10 will be a described.

Sample 10 has a width W₈ of the first conductivity-type region 130 narrower than the width W₄ of the first conductivity-type region 130 of Sample 5. The width W₈ may be, for example, not less than 3 μm and not more than 7 μm (preferably, about 5 μm). More specifically, in Sample 10, the outermost trench of the second outer peripheral trenches 42 forms the boundary trench 76. Therefore, all the second outer peripheral trenches 42 are formed by penetrating through the second impurity region 122.

Further, in Sample 10, the second boundary portion 77 is formed in a region directly under the third conductive film 53 and also further outside than a connection position of the outer periphery contact plug 135 in the semiconductor chip 12. Thereby, the first conductivity-type region 130 is formed so as to include internally the outer periphery contact plug 135 and also face the third conductive film 53 in a thickness direction of the semiconductor chip 12. The other constitutions of Sample 10 are the same as Sample 5. In order to change the width W₄ of the first conductivity-type region 130 to the width W₈, a pattern (width) of the mask used in forming the second impurity region 122 may be changed.

Next, with reference to FIG. 20 and FIG. 21, Sample 11 will be a described.

In Sample 11, the second portion 71 of the second impurity region 122 of Sample 5 is omitted. Therefore, the first conductivity-type region 130 is formed so as to reach the first end surfaces 31A, 31B and the second end surfaces 32A, 32B of the semiconductor chip 12 from the boundary trench 76. Thereby, the first conductivity-type region 130 is formed so as to include internally the outer periphery contact plug 135 and also face the third conductive film 53 in a thickness direction of the semiconductor chip 12. The other constitutions of Sample 11 are the same as Sample 5.

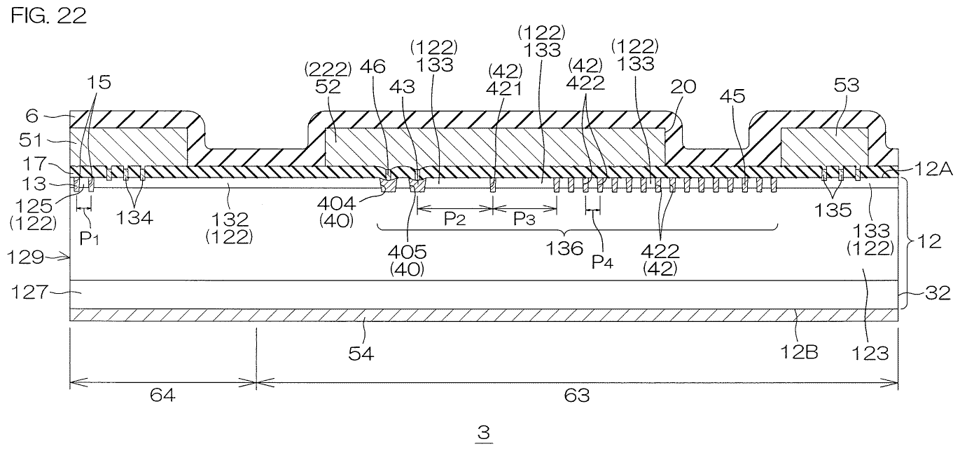

Then, a high temperature reverse bias test (HTRB) is performed by referring to Samples 5 to 11 and Sample 12 (FIG. 22) in which the first conductivity-type region 130 is not formed. In the HTRB test, in an environment of 150° C., a voltage of −100V is applied to the fourth conductive film 54 (rear-surface drain electrode) and the first conductive film 51 (front-surface source electrode) continuously for 1000 hours. On the other hand, a determination is made for current-voltage characteristics at a room temperature (initial characteristics). Then, the initial characteristics are compared with the characteristics after an elapse of not less than 250 hours after start of the HTRB test to confirm whether a leakage current is reduced by formation of the first conductivity-type region 130.

As a result, in Samples 5 to 11, the leakage current is suppressed satisfactorily even after application of a stress for not less than 250 hours. In particular, in Samples 5 and 7 in which the widths W₄ and W₆ of the first conductivity-type region 130 are from not less than 8 μm to not more than 15 μm, the leakage current is hardly changed in value in relation to an initial leakage current before application of the stress.

In this respect, a simulation is performed in each of Samples 5 to 12 to check a current path upon application of a reverse direction voltage under the same conditions as the HTRB test. As a result, in Sample 12 in which the first conductivity-type region 130 is not formed, a current flowing in a thickness direction of the semiconductor chip 12 is found to partially leak into the third conductive film 53 (outer peripheral electrode) along the first principal surface 12A. In contrast thereto, in Samples 5 to 11, the leakage into the outer periphery portion is not confirmed. That is, a selective removal of the second impurity region 122 in the outer peripheral region 63 is considered to enable suppression of a composition which leaks from an outer periphery of the semiconductor chip 12.

As described so far, the semiconductor device 1 according to the preferred embodiments of the present disclosure is found to provide a structure capable of reducing a reverse direction leakage current.

### <Effect on Improvement in Device Withstand Voltage by Formation of First Conductivity-Type Region 130 of Second Impurity Region 122>

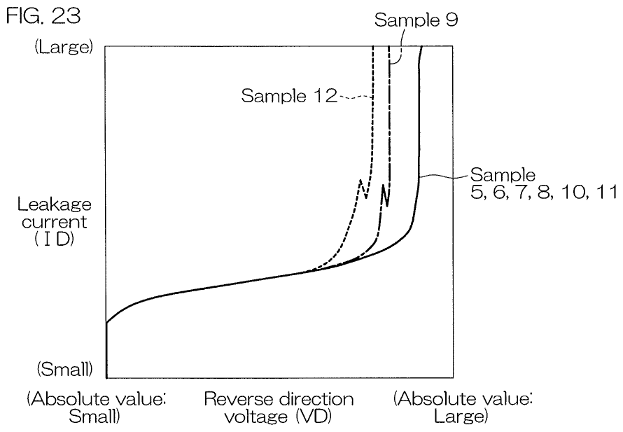

Next, a simulation is performed to confirm whether the device withstand voltage is improved by formation of the first conductivity-type region 130. FIG. 23 is a view which shows results thereof. In FIG. 23, the horizontal axis represents a magnitude of a reverse direction voltage (drain voltage VD) applied between a source and a drain and shows that the more the horizontal axis moves closer to the right side, the larger an absolute value of the reverse direction voltage becomes. In FIG. 23, the vertical axis represents a magnitude of a leakage current (drain current ID) when the reverse direction voltage is applied between the source and the drain and shows that the more the vertical axis moves closer to the upper side, the larger the leakage current becomes.

With reference to FIG. 23, all Samples 5 to 11 undergo breakdown at a voltage of V₂ or V₃ higher than a breakdown voltage V₁ of Sample 12. In particular, Samples 5 to 8 and Samples 10 to 11 excluding Sample 9 in which a width W₇ of the first conductivity-type region 130 in FIG. 17 is relatively wide (for example, not less than 20 μm and not more than 27 μm) undergo breakdown at a higher voltage of V₃. That is, it is found that, although the device withstand voltage can be improved by formation of the first conductivity-type region 130, the device withstand voltage can be further improved by not broadening the width of the first conductivity-type region 130 excessively.

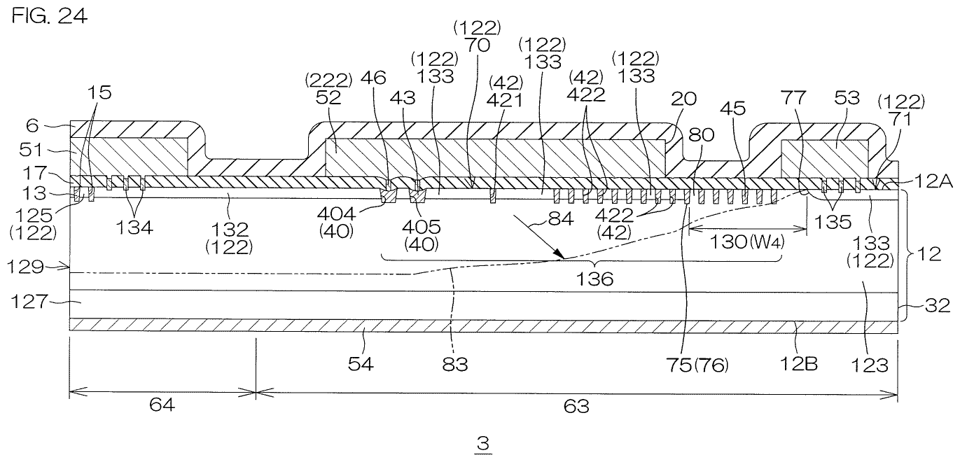

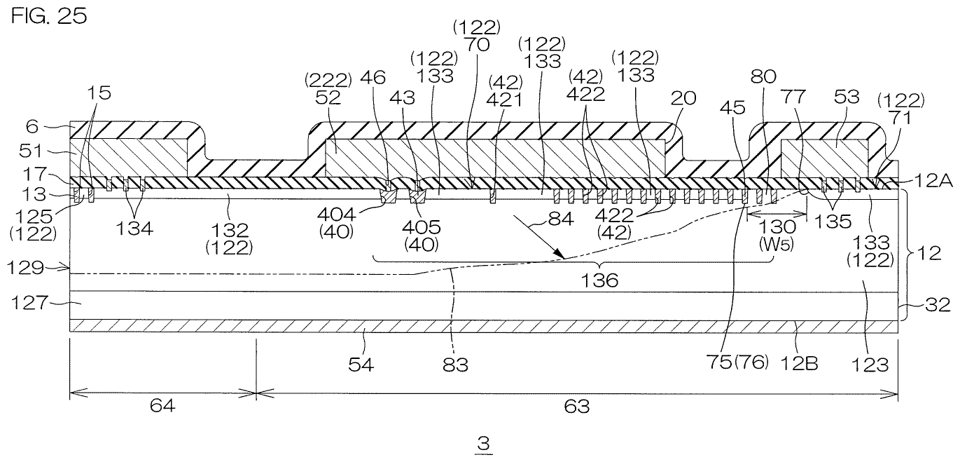

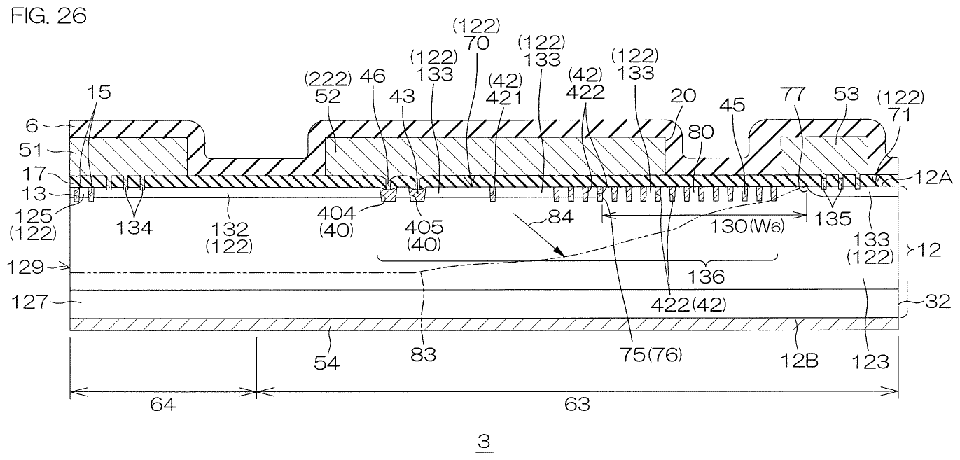

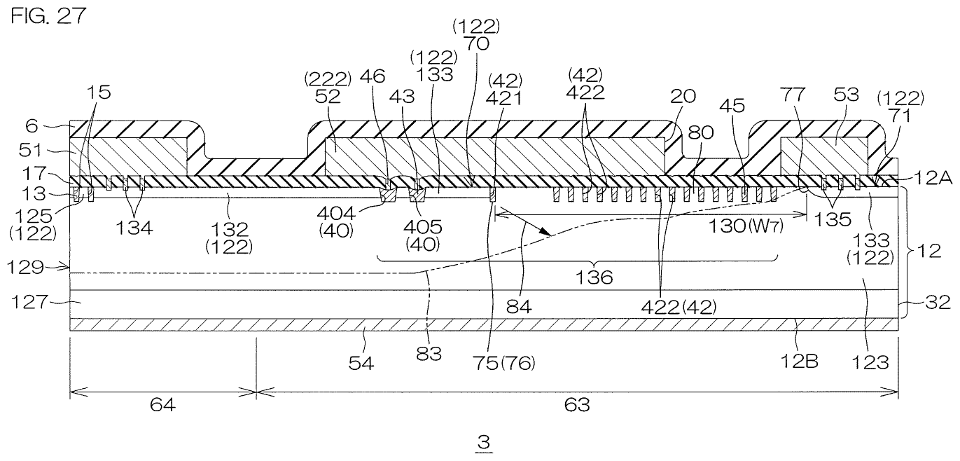

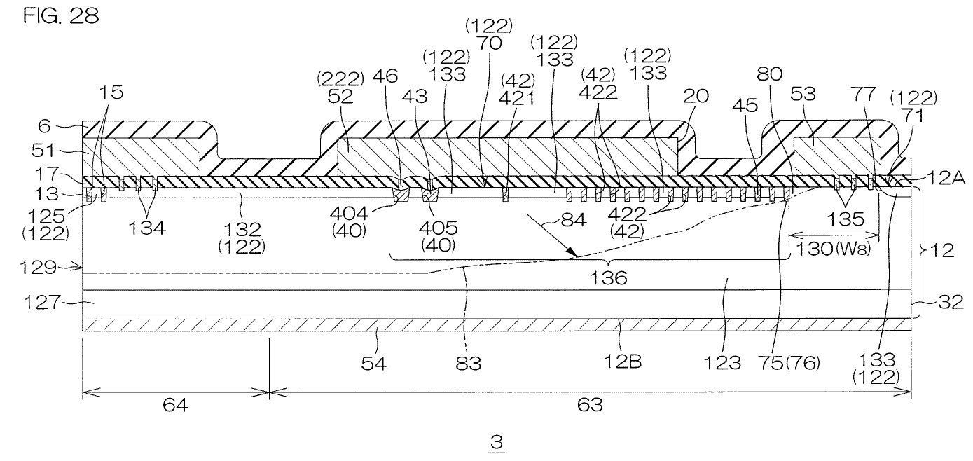

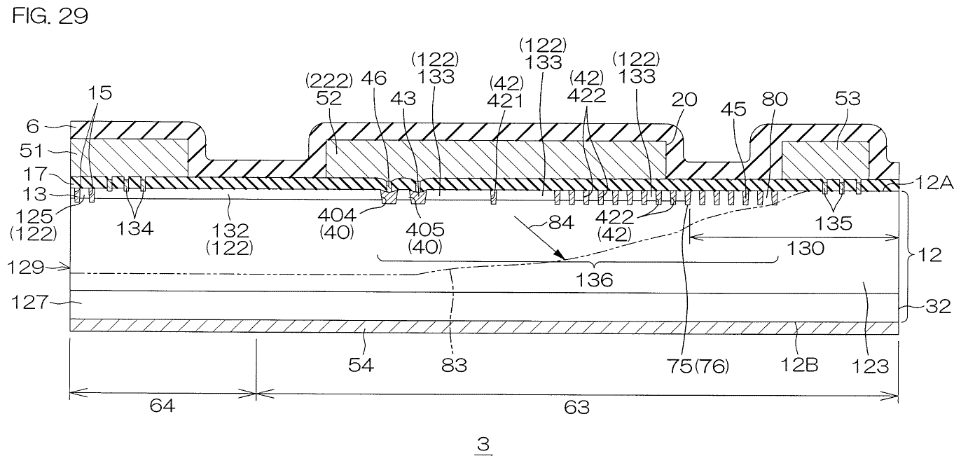

In this respect, a simulation is performed to examine an elongation of the depletion layer 83 in the outer peripheral region 63 of each of Samples 5 to 11. As a result, in Sample 9, since the first conductivity-type region 130 in which the second impurity region 122 has been removed continues from the first trench 421 to a region directly under the third conductive film 53, an effect that elongates the depletion layer 83 outward is weakened, for example, in the vicinity of a portion indicated by an arrow 84 in FIG. 27. On the other hand, as shown in FIG. 24 to FIG. 26 and FIG. 28 to FIG. 29, in Samples 5 to 8 and in Samples 10 to 11, the depletion layer 83 is elongated satisfactorily even in the vicinity of the portion indicted by the arrow 84. The effect on improvement in device withstand voltage is considered to be influenced by a difference in elongation of the depletion layer 83.

As described so far, the semiconductor device 1 according to the preferred embodiment of the present disclosure is found to provide a structure capable of improving the device withstand voltage.

### <Effect on Improvement in Device Withstand Voltage by Changing Pitch of Outer Peripheral Trenches 40, 42>

Hereinafter, a description will be given of improvement in device withstand voltage by changing the number of the first outer peripheral trenches 40 and the outer peripheral pitches P₂, P₃, P₄ on the basis of Samples 13 to 16.

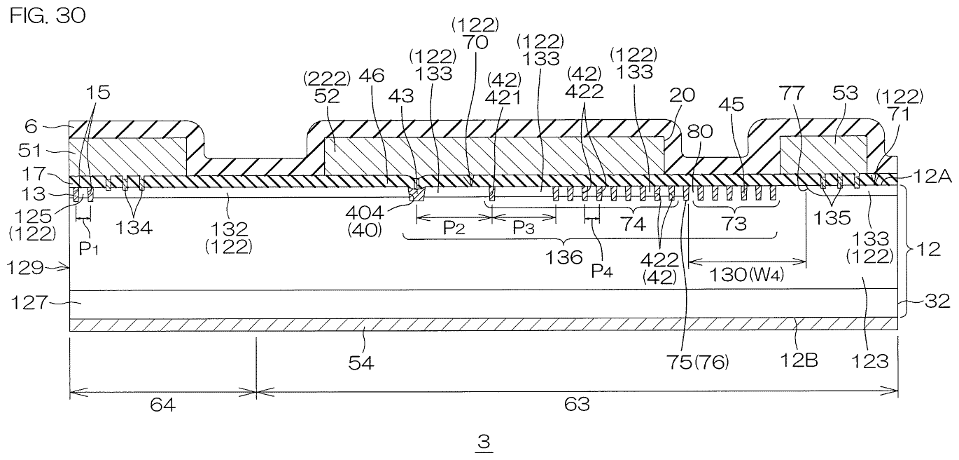

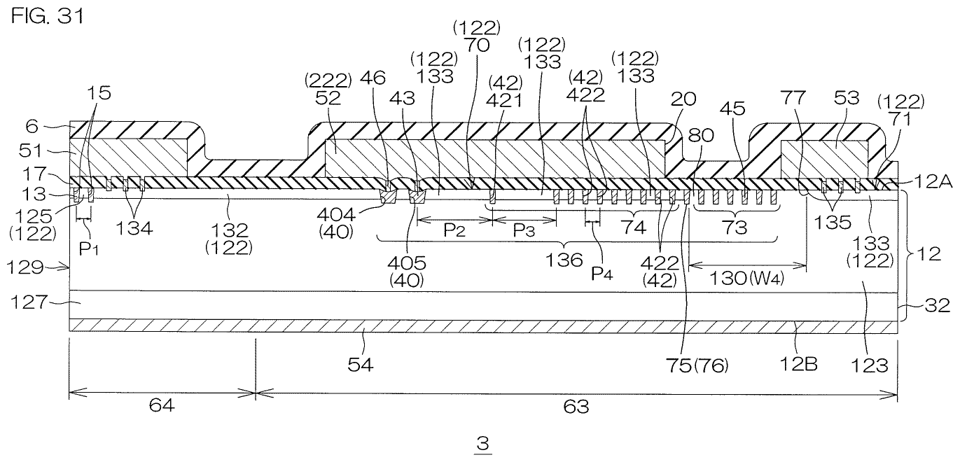

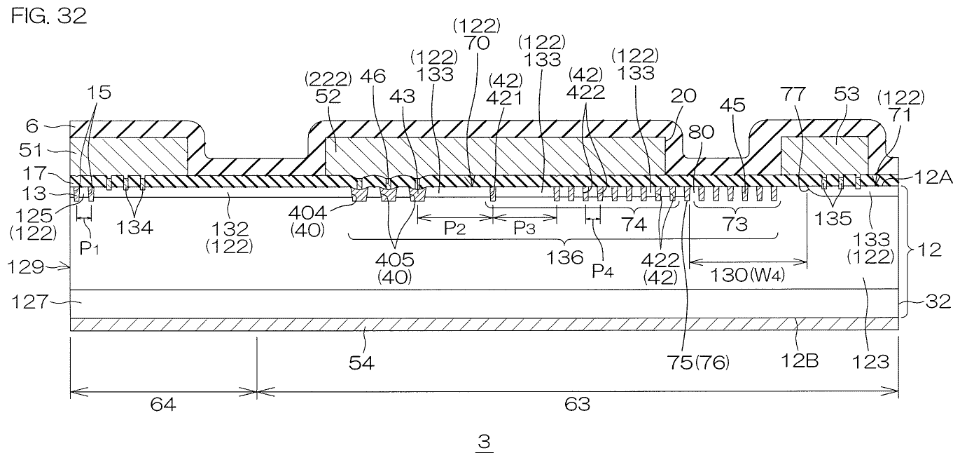

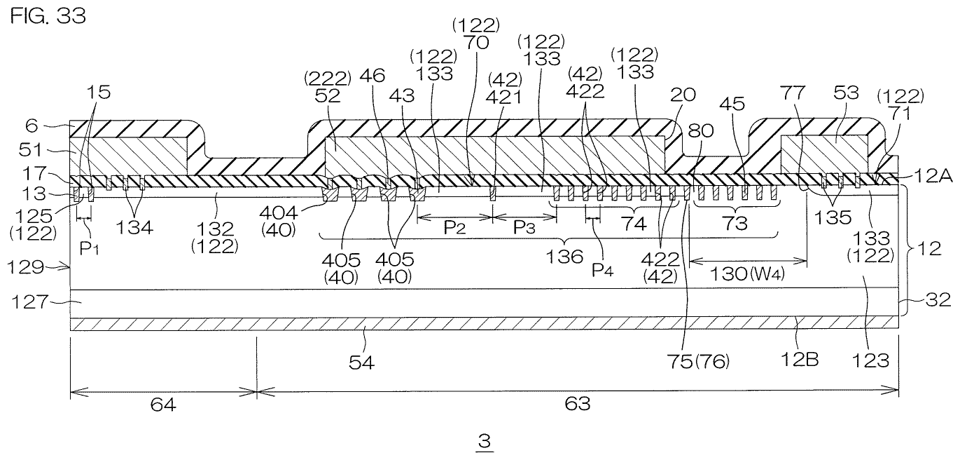

FIG. 30 is a schematic sectional view of the semiconductor element 3 according to Sample 13. FIG. 31 is a schematic sectional view of the semiconductor element 3 according to Sample 13. FIG. 32 is a schematic sectional view of the semiconductor element 3 according to Sample 14. FIG. 33 is a schematic sectional view of the semiconductor element 3 according to Sample 15.

Although the structures of Samples 13 to 16 are fundamentally the same as Sample 5, the following are structures different from those of Sample 5.

First, Sample 13 is different in that the first outer peripheral trench 40 is one from Sample 5 which has the two first outer peripheral trenches 40. In Sample 13, the outer trench 405 of Sample 5 is omitted. Sample 13 has the same structure as Sample 5.

Sample 14 is different in that the number of the first outer peripheral trenches 40 is three from Sample 5 which has the two first outer peripheral trenches 40. In Sample 14, the first outer peripheral trench 40 is added to a further inner side (active region 64 side) than the inner trench 404 of Sample 5, and the added first outer peripheral trench 40 is given as the inner trench 404. On the other hand, the existing first outer peripheral trench 40 of Sample 5 is given as the outer trench 405.

Sample 15 is different in that the number of the first outer peripheral trenches 40 is four from Sample 5 which has the two first outer peripheral trenches 40. In Sample 14, the two first outer peripheral trenches 40 are added to a further inner side (active region 64 side) than the inner trench 404 of Sample 5 and, of the added first outer peripheral trenches 40, the inner trench is given as the inner trench 404. On the other hand, of the added first outer peripheral trenches 40, the outer trench and an existing first outer peripheral trench 40 of Sample 5 are given as the outer trench 405.

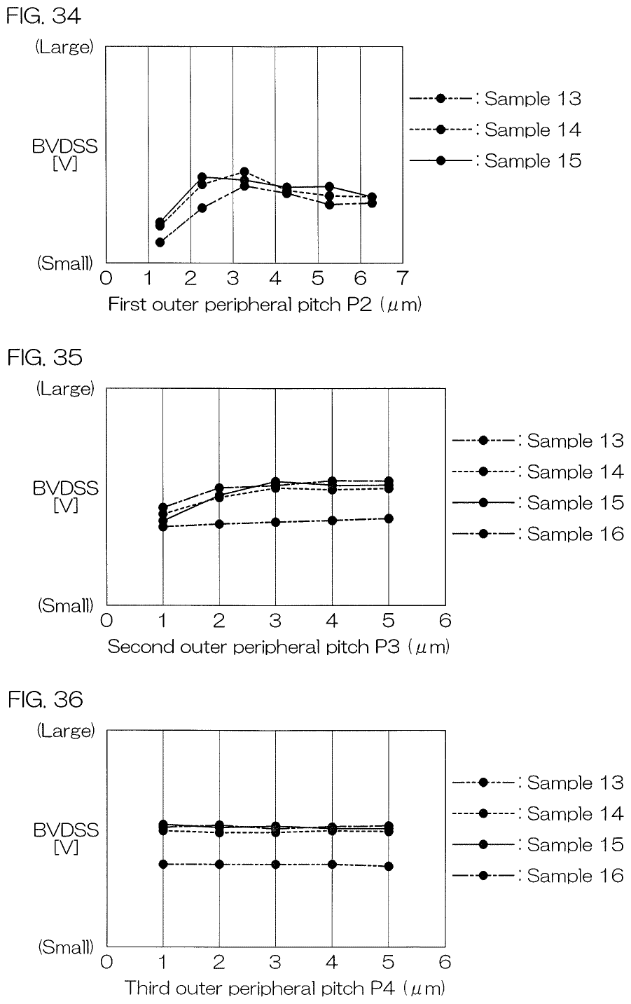

Next, a simulation is performed to examine a change in breakdown voltage by changing the outer peripheral pitches P₂, P₃, P₄ when the outer peripheral pitches P₂, P₃, P₄ of each of Samples 13 to 16 are given as variables. FIG. 34 to FIG. 36 are views which show the results thereof.

FIG. 34 is a view which shows a relationship between the first outer peripheral pitch P₂ and the device withstand voltage and also a view which shows the examination results of Samples 13 to 15. In FIG. 34, the horizontal axis represents a size of the first outer peripheral pitch P₂. In FIG. 34, the vertical axis shows a magnitude of breakdown voltage (BVDSS) when a reverse direction voltage is applied between a source and a drain and shows that the more the vertical axis moves closer to the upper side, the larger the breakdown voltage (BVDSS) becomes.

In an examination of the first outer peripheral pitch P₂, as values of the first outer peripheral pitch P₂, 1.28 μm, 2.28 μm, 3.28 μm, 4.28 μm, 5.28 μm and 6.28 μm are adopted to confirm a breakdown voltage at each of the first outer peripheral pitches P₂. It is noted that, since the pitch P₁ of the gate trench 15 is set at 1 μm, the respective values of the first outer peripheral pitch P₂ may be defined to be 1.28 times, 2.28 times, 3.28 times, 4.28 times, 5.28 times and 6.28 times the pitch P₁ (cell pitch) of the gate trench 15.

With reference to FIG. 34, breakdown voltages of Samples 13 to 15 are compared to find that, in each of Samples 13 to 15, a relatively high breakdown voltage is attained where the first outer peripheral pitch P₂ is 2.28 μm (2.28 times the cell pitch), 3.28 μm (3.28 times the cell pitch) and 4.28 μm (4.28 times the cell pitch). As described so far, it is apparent that the device withstand voltage can be particularly improved where the first outer peripheral pitch P₂ is not less than 2.0 μm and not more than 4.0 μm or where the first outer peripheral pitch P₂ is not less than 2 times and not more than 4 times the pitch P₁ of the gate trench 15.

In this respect, a simulation is performed to confirm a breakdown site by referring to an impact ionization coefficient inside the semiconductor chip 12. As a result, in the case of the first outer peripheral pitch P₂ which is 1.28 μm, that is where a distance is close between the first outer peripheral trench 40 in which the first embedded electrode 43 fixed at a gate potential is embedded and the second outer peripheral trench 42 in which the electrically floating second embedded electrode 45 is embedded, a breakdown selectively occurs in the vicinity of the first outer peripheral trench 40. Further, in the case of the first outer peripheral pitch P₂ which is 6.28 μm, that is where a distance is far between the first outer peripheral trench 40 in which the first embedded electrode 43 fixed at a gate potential is embedded and the second outer peripheral trench 42 in which the electrically floating second embedded electrode 45 is embedded, a breakdown selectively occurs in the vicinity of the second outer peripheral trench 42.

In contrast thereto, where the first outer peripheral pitch P₂ is 3.28 μm, a breakdown occurs both in the first outer peripheral trench 40 in which the first embedded electrode 43 fixed at a gate potential is embedded and the second outer peripheral trench 42 in which the electrically floating second embedded electrode 45 is embedded. That is, where the first outer peripheral pitch P₂ is neither excessively narrow nor excessively wide, an electric field can be dispersed in the first outer peripheral trench 40 and the second outer peripheral trench 42, which is preferable in view of improvement in device withstand voltage.

FIG. 35 is a view which shows a relationship between the second outer peripheral pitch P₃ and the device withstand voltage and a view which shows examination results of Samples 13 to 16. In FIG. 35, the horizontal axis represents a size of the second outer peripheral pitch P₃. In FIG. 35, the vertical axis represents a magnitude of breakdown voltage (BVDSS) on application of a reverse direction voltage between a source and a drain, showing that the more the vertical axis moves closer to the upper side, the larger the breakdown voltage (BVDSS) becomes.

In an examination on the second outer peripheral pitch P₃, a value of the first outer peripheral pitch P₂ is fixed at 3.28 μm and, as values of the second outer peripheral pitch P₃, 1 μm, 2 μm, 3 μm, 4 μm and 5 μm are adopted to confirm a breakdown voltage at each of the second outer peripheral pitches P₃. It is noted that, since the pitch P₁ of the gate trench 15 is set at 1 μm, the respective values of the second outer peripheral pitch P 3 may be defined as 1 time, 2 times, 3 times, 4 times and 5 times the pitch P₁ (cell pitch) of the gate trench 15.

With reference to FIG. 35, breakdown voltages of Samples 13 to 16 are compared to find that a relatively high breakdown voltage is attained in each of Samples 13 to 16 where the second outer peripheral pitch P₃ is 2 μm (2 times the cell pitch), 3 μm (3 times the cell pitch), 4 μm (4 times the cell pitch) and 5 μm (5 times the cell pitch). Further, in a range that the second outer peripheral pitch P₃ is from 2 μm to 5 μm, an increase in second outer peripheral pitch P₃ does not substantially influence the breakdown voltage. As described so far, it is apparent that the device withstand voltage can be improved in particular where the second outer peripheral pitch P₃ is not less than 2.0 μm and not more than 6.0 μm or where the second outer peripheral pitch P₃ is not less than 2 times and not more than 6 times the pitch P₁ of the gate trench 15. In view of recommending a miniaturization of the semiconductor element 3, it is preferable that the second outer peripheral pitch P₃ is kept approximately equal in size to the first outer peripheral pitch P₂ or smaller than the first outer peripheral pitch P₂.

FIG. 36 is a view which shows a relationship between the third outer peripheral pitch P₄ and the device withstand voltage and a view which shows examination results of Samples 13 to 16. In FIG. 36, the horizontal axis represents a size of the third outer peripheral pitch P₄. In FIG. 36, the vertical axis represents a magnitude of breakdown voltage (BVDSS) on application of a reverse direction voltage between a source and a drain and shows that the more the vertical axis moves closer to the upper side, the larger the breakdown voltage (BVDSS) becomes.

In the examination on the third outer peripheral pitch P₄, a value of the first outer peripheral pitch P₂ and a value of the second outer peripheral pitch P₃ are fixed respectively at 3.28 μm and 3 μm, then as values of the third outer peripheral pitch P₄, 1 μm, 2 μm, 3 μm, 4 μm and 5 μm are adopted to confirm a breakdown voltage in each of the third outer peripheral pitches P₄. It is noted that, since the pitch P₁ of the gate trench 15 is set at 1 μm, the values of the third outer peripheral pitch P₄ may be respectively defined as 1 time, 2 times, 3 times, 4 times and 5 times the pitch P₁ (cell pitch) of the gate trench 15.

With reference to FIG. 36, the breakdown voltages of Samples 13 to 16 are compared to find that the breakdown voltage is hardly changed in any of Samples 13 to 16 where a value of the third outer peripheral pitch P₄ is in a range of 2 μm to 5 μm. As described so far, in view of recommending a miniaturization of the semiconductor element 3, the third outer peripheral pitch P₄ is preferably kept approximately equal to the pitch P₁ of the gate trench 15 (about 1 μm in the preferred embodiment). It is thereby apparent that the semiconductor element 3 can be miniaturized and also improved in device withstand voltage.

Although the preferred embodiments of the present disclosure have been described above, the present disclosure can be implemented in still other preferred embodiments.

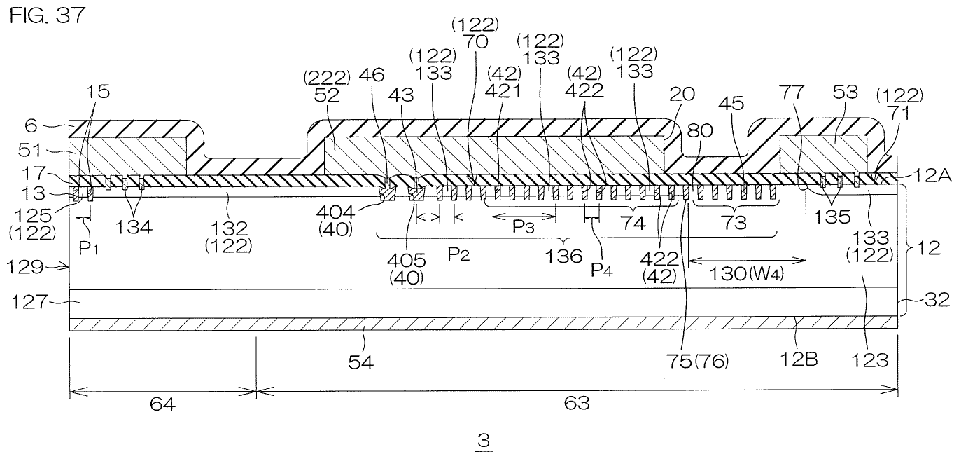

For example, in the verification results based on Samples 1 to 11, the size of the outer peripheral pitch P₂, P₃, or P₄ does not particularly contribute to an effect on reduction in leakage current. Therefore, as shown in FIG. 37, even when the first outer peripheral pitch P₂, the second outer peripheral pitch P₃ and the third outer peripheral pitch P₄ are equal to each other, the leakage current can be satisfactorily reduced as long as the first conductivity-type region 130 is formed.

Further, there may be adopted, for example, a constitution in which the conductivity-types of the respective semiconductor portions of the semiconductor device 1 are inverted. In the semiconductor device 1, for example, a p-type portion may be replaced with an n-type and an n-type portion may be replaced with a p-type.

Further, in the above-described preferred embodiments, the MISFET is referred as an example of the element structure of the semiconductor device 1. However, the element structure of the semiconductor device 1 may be, for example, an IGBT (Insulated Gate Bipolar Transistor), etc.

The preferred embodiments of the present disclosure so far described are examples in every respect and should not be construed as limited in any manner, and are intended to include changes in every respect.

Features added below can be extracted from the present specification and drawings.

### Appendix 1-1

A semiconductor device (1) including:
a semiconductor chip (12) which has a first principal surface (12A) and a second principal surface (12B) at the opposite side of the first principal surface (12A) as well as end surfaces (31A, 31B, 32A, 32B) that surround the first principal surface (12A) in which an active region (64) and an outer peripheral region (63) around the active region (64) are provided at the first principal surface (12A) side,
a first electrode (51) which is formed on the first principal surface (12A) of the semiconductor chip (12),
a second electrode (54) which is formed on the second principal surface (12B) of the semiconductor chip (12),
a first conductivity-type first region (123, 129) which is formed in the semiconductor chip (12) and electrically connected to the second electrode (54),
a vertical-type semiconductor element structure (14) which is formed in the active region (64) and allows a current to flow between the first electrode (51) and the second electrode (54),
an outer peripheral electrode (53) which is formed on the first principal surface (12A) of the semiconductor chip (12) so as to be physically separated from the first electrode (51) and connected to the semiconductor chip (12) in the outer peripheral region (63), and
a second conductivity-type well region (122) which is formed continuously from the active region (64) to the outer peripheral region (63) at a surface layer portion of the first region (123, 129) to constitute at least a part of the semiconductor element structure (14), in which
in the outer peripheral region (63), there is present a first conductivity-type region (130) in which the well region (122) is not selectively formed.

### Appendix 1-2

The semiconductor device (1) according to Appendix 1-1 including a trench group (136) which includes a plurality of annular trenches (40, 42) that are formed in the outer peripheral region (63) further inside than the outer peripheral electrode (53) and surrounds the active region (64), in which
the first conductivity-type region (130) is formed so as to include internally some of the plurality of annular trenches (40, 42) and also overlap the trench group (136).

### Appendix 1-3

The semiconductor device (1) according to Appendix 1-1 or Appendix 1-2 including an outer periphery contact portion (135) which connects the outer peripheral electrode (53) and the semiconductor chip (12), in which
the first conductivity-type region (130) is formed so as to include internally the outer periphery contact portion (135) and also face the outer peripheral electrode (53) in a thickness direction of the semiconductor chip (12).

### Appendix 1-4

The semiconductor device (1) according to Appendix 1-3 in which
the first conductivity-type region (130) is formed so as to reach the end surface (31A, 31B, 32A, 32B) of the semiconductor chip (12) and
the well region (122) is formed in an inner region surrounded by the first conductivity-type region (130).

### Appendix 1-5

The semiconductor device (1) according to any one of Appendix 1-1 to Appendix 1-3 in which
the first conductivity-type region (130) is formed in an annular shape which surrounds the active region (64) and
the well region (122) is divided into a first portion (70) formed in an inner region which is surrounded by the first conductivity-type region (130) and a second portion (71) formed in an annular outer region which surrounds the first conductivity-type region (130).

### Appendix 1-6

The semiconductor device (1) according to Appendix 1-in which
a width (W₄, W₆) of the first conductivity-type region (130) held between the first portion (70) and the second portion (71) is not less than 8 μm and not more than 15 μm.

### Appendix 1-7

The semiconductor device (1) according to any one of Appendix 1-1 to Appendix 1-6 in which
the first conductivity-type region (130) is formed by a part (80) of the first region (123, 129) which is exposed from the first principal surface (12A) of the semiconductor chip (12).

### Appendix 1-8

The semiconductor device (1) according to any one of Appendix 1-1 to Appendix 1-6 in which
the first conductivity-type region (130) includes a second region (78) which is selectively formed at a surface layer portion of the first region (123, 129) and has a first conductivity-type impurity concentration higher than the first conductivity-type impurity concentration of the first region (123, 129).

### Appendix 1-9

The semiconductor device (1) according to Appendix 1-1 in which
the semiconductor element structure (14) includes a cell trench (15), a control electrode (13) embedded in the cell trench (15) and a channel region (125) formed laterally in the cell trench (15) and constituted of the well region (122),
the semiconductor device (1) including:
a first outer peripheral trench (40) which is annular and formed further inside than the outer peripheral electrode (53) in the outer peripheral region (63),
a first embedded electrode (43) which is embedded in the first outer peripheral trench (40) and electrically connected to the control electrode (13),
a second outer peripheral trench group (42) which includes a plurality of second outer peripheral trenches (42) that are annular and formed in the outer peripheral region (63) further outside than the first outer peripheral trench (40) and also further inside than the outer peripheral electrode (53) and physically separated from the first outer peripheral trench (40) and
a second embedded electrode (45) which is embedded in the second outer peripheral trench (42) and electrically separated from the first embedded electrode (43), in which
the well region (122) continues in a lateral direction along the first principal surface (12A) from the channel region (125) excluding a portion that forms the first outer peripheral trench (40) and a portion that forms the second outer peripheral trench group (42) as well as the first conductivity-type region (130).

### Appendix 1-10

The semiconductor device (1) according to Appendix 1-9 in which
the first conductivity-type region (130) is formed so as to selectively include internally some of the plurality of second outer peripheral trench groups (42) and also overlap the second outer peripheral trench group (42) and
the first outer peripheral trench (40) is formed so as to penetrate through the well region (122) in a thickness direction of the semiconductor chip (12) and reach the first region (123).

### Appendix 1-11

The semiconductor device (1) according to Appendix 1-9 or Appendix 1-10 including an outer periphery contact portion (135) which connects the outer peripheral electrode (53) and the semiconductor chip (12) in which the first conductivity-type region (130) is formed so as to include internally the outer periphery contact portion (135) and also face the outer peripheral electrode (53) in a thickness direction of the semiconductor chip (12).

### Appendix 1-12

The semiconductor device (1) according to any one of Appendix 1-9 to Appendix 1-11 in which
the second outer peripheral trench group (42) includes a first trench (421) which is formed at an interval of a first outer peripheral pitch (P₂) from the first outer peripheral trench (40) at the end surface (31A, 31B, 32A, 32B) side and a plurality of second trenches (422) which are formed at an interval of a second outer peripheral pitch (P 3) from the first trench (421) at the end surface (31A, 31B, 32A, 32B) sides and arrayed at an interval of a third outer peripheral pitch (P₄) narrower than the first outer peripheral pitch (P₂) and the second outer peripheral pitch (P₃) and
the plurality of second trenches (422) include a boundary trench (76) which forms a first boundary portion (75) between the well region (122) and the first conductivity-type region (130).

### Appendix 1-13

The semiconductor device (1) according to Appendix 1-12 in which
the well region (122) includes a first portion (70) which is formed in an inner region surrounded by the boundary trench (76) and a second portion (71) which has a second boundary portion (77) with the first conductivity-type region (130) in a region directly under the outer peripheral electrode (53) and is formed in an annular outer region further at the end surface (31A, 31B, 32A, 32B) sides than the second boundary portion (77).

### Appendix 1-14

The semiconductor device (1) according to Appendix 1-13 in which
a width (W₄, W₆) of the first conductivity-type region (130) held between the first portion (70) and the second portion (71) is not less than 8 μm and not more than 15 μm.

### Appendix 1-15

The semiconductor device (1) according to Appendix 1-12 in which
the first conductivity-type region (130) is formed so as to reach from the boundary trench (76) to the end surfaces (31A, 31B, 32A, 32B) of the semiconductor chip (12) and
the well region (122) is formed in an inner region surrounded by the boundary trench (76).

### Appendix 1-16

The semiconductor device (1) according to any one of Appendix 1-9 to Appendix 1-15 in which
the well region (122) includes a first potential well region (132) which is formed in an inner region surrounded by the first outer peripheral trench (40) and electrically connected to the first electrode (51) and a floating region (133) which is formed in an outer region of the first outer peripheral trench (40) and kept in an electrically floating state.

### Appendix 1-17

The semiconductor device (1) according to any one of Appendix 1-1 to Appendix 1-16 which has a withstand voltage of not less than 100V.

### Appendix 1-18

The semiconductor device (1) according to any one of Appendix 1-1 to Appendix 1-17 in which the first region (123, 129) has a specific resistance of not less than 3.5 Ω·cm and not more than 4.5 Ω·cm.

### Appendix 1-19

The semiconductor device (1) according to any one of Appendix 1-1 to Appendix 1-18 in which
the semiconductor chip (12) includes a first conductivity-type semiconductor substrate (127) which has a first impurity concentration and a first conductivity-type epitaxial layer (129) which is formed on the semiconductor substrate (127) and has a second impurity concentration lower than the first impurity concentration to constitute the first region (123) and
the epitaxial layer (129) has a thickness of not less than 7 μm and not more than 15 μm.

### Appendix 1-20

The semiconductor device (1) according to Appendix 1-19 in which
the first impurity concentration is not less than 1×10¹⁸ cm⁻³ and not more than 1×10²⁰ cm⁻³ and
the second impurity concentration is not less than 1×10¹⁵ cm⁻³ and not more than 1×10¹⁹ cm⁻³.

### Appendix 1-21

The semiconductor device (1) according to any one of Appendix 1-9 to Appendix 1-16 in which
the channel region (125) includes a side portion (124) which forms a side surface of the cell trench (15) and a convex bottom portion (126) which expands outward to the second principal surface (12B) side from a lower end of the side portion (124) so as to separate from the side surface of the cell trench (15) and
the bottom portion of the channel region (125) is positioned further at the first principal surface (12A) side than a lower end (152) of the cell trench (15).

### Appendix 1-22

The semiconductor device (1) according to any one of Appendix 1-9 to Appendix 1-16 in which
the first outer peripheral trench (40) is formed at a width (W₂) larger than the cell trench (15).

### Appendix 1-23

The semiconductor device (1) according to Appendix 1-22 in which the first outer peripheral trench (40) has a depth (D₂) deeper than the cell trench (15).

### Appendix 1-24

The semiconductor device (1) according to any one of Appendix 1-9 to Appendix 1-16 in which
the semiconductor element structure (14) includes a first conductivity-type source region (121), a second conductivity-type channel region (125) and a first conductivity-type drift region (123) which are formed sequentially from the first principal surface (12A) of the semiconductor chip (12) in a depth direction of the cell trench (15) and
the control electrode (13) includes a gate electrode (13) which forms a channel in the channel region (125).

### Appendix 1-25

The semiconductor device (1) according to any one of Appendix 1-1 to Appendix 1-24 in which
the semiconductor chip (12) contains a silicon chip.

### Appendix 1-26

The semiconductor device (1) according to any one of Appendix 1-12 to Appendix 1-15 in which
the cell trench (15) is arrayed in the active region (64) at a predetermined cell pitch (P₁), and
the first outer peripheral pitch (P₂) is not less than 2 times and not more than 4 times the cell pitch (P₁).

### Appendix 1-27

The semiconductor device (1) according to Appendix 1-26 in which
the second outer peripheral pitch (P₃) is not less than 2 times and not more than 6 times the cell pitch (P₁).

### Appendix 1-28

The semiconductor device (1) according to Appendix 1-26 or Appendix 1-27 in which the second outer peripheral pitch (P₃) is smaller than the first outer peripheral pitch (P₂).

### Appendix 1-29

The semiconductor device (1) according to any one of Appendix 1-26 to Appendix 1-28 in which
the third outer peripheral pitch (P₄) is equal to the cell pitch (P₁).

### Appendix 1-30

The semiconductor device (1) according to any one of Appendix 1-26 to Appendix 1-29 in which
the cell pitch (P₁) is not less than 0.8 μm and not more than 1.2 μm and
the first outer peripheral pitch (P₂) is not less than 2.0 μm and not more than 4.0 μm.

### Appendix 1-31

The semiconductor device (1) according to any one of Appendix 1-26 to Appendix 1-29 in which
the cell pitch (P₁) is not less than 0.8 μm and not more than 1.2 μm,
the first outer peripheral pitch (P₂) is not less than 2.0 μm and not more than 4.0 μm and
the second outer peripheral pitch (P₃) is not less than 2.0 μm and not more than 6.0 μm.

### Appendix 2-1

A semiconductor device (1) including:
a semiconductor chip (12) which has a first principal surface (12A) and a second principal surface (12B) at the opposite side of the first principal surface (12A) in which an active region (64) and an outer peripheral region (63) around the active region (64) are provided at the first principal surface (12A) side,
a first electrode (51) which is formed on the first principal surface (12A) of the semiconductor chip (12),
a second electrode (54) which is formed on the second principal surface (12B) of the semiconductor chip (12),
a first conductivity-type first region (123, 129) which is formed in the semiconductor chip (12) and electrically connected to the second electrode (54),
a semiconductor element structure (14) which includes a cell trench (15) formed in the active region (64) and arrayed at a predetermined cell pitch (P₁), a control electrode (13) embedded in the cell trench (15) and a second conductivity-type channel region (125) formed laterally in the cell trench (15) and allows a current to flow between the first electrode (51) and the second electrode (54),
a first outer peripheral trench (40) which is annular and formed in the outer peripheral region (63),
a first embedded electrode (43) which is embedded in the first outer peripheral trench (40) and electrically connected to the control electrode (13),
a second outer peripheral trench group (42) which includes a plurality of second outer peripheral trenches (42) that are annular and formed in the outer peripheral region (63) further outside than the first outer peripheral trench (40) and physically separated from the first outer peripheral trench (40), and
a second embedded electrode (45) which is embedded in the second outer peripheral trench (42) and electrically separated from the first embedded electrode (43), in which
a first outer peripheral pitch (P₂) between the first outer peripheral trench (40) and the second outer peripheral trench group (42) is not less than 2 times and not more than 4 times the cell pitch (P₁).

### Appendix 2-2

The semiconductor device (1) according to Appendix 2-1 in which
the second outer peripheral trench group (42) includes a first trench (421) which is formed at an interval of the first outer peripheral pitch (P₂) outside from the first outer peripheral trench (40) and a second trench (422) which is formed at an interval of a second outer peripheral pitch (P₃) outside from the first trench (421) and
the second outer peripheral pitch (P₃) is not less than 2 times and not more than 6 times the cell pitch (P₁).

### Appendix 2-3

The semiconductor device (1) according to Appendix 2-2 in which
the second outer peripheral pitch (P₃) is smaller than the first outer peripheral pitch (P₂).

### Appendix 2-4

The semiconductor device (1) according to Appendix 2-2 or Appendix 2-3 in which the second outer peripheral trench group (42) includes the plurality of second trenches (422) which are arrayed at an interval of a third outer peripheral pitch (P 4) narrower than the first outer peripheral pitch (P₂) and the second outer peripheral pitch (P₃) and
the third outer peripheral pitch (P₄) is equal to the cell pitch (P₁).

### Appendix 2-5

The semiconductor device (1) according to any one of Appendix 2-1 to Appendix 2-4 in which
the cell pitch (P₁) is not less than 0.8 μm and not more than 1.2 μm and
the first outer peripheral pitch (P₂) is not less than 2.0 μm and not more than 4.0 μm.

### Appendix 2-6

The semiconductor device (1) according to any one of Appendix 2-2 to Appendix 2-4 in which
the cell pitch (P₁) is not less than 0.8 μm and not more than 1.2 μm,
the first outer peripheral pitch (P₂) is not less than 2.0 μm and not more than 4.0 μm and the second outer peripheral pitch (P₃) is not less than 2.0 μm and not more than 6.0 μm.

### Appendix 2-7

A semiconductor device (1) including:
a semiconductor chip (12) which has a first principal surface (12A) and a second principal surface (12B) at the opposite side of the first principal surface (12A) in which an active region (64) and an outer peripheral region (63) around the active region (64) are provided at the first principal surface (12A) side,
a first electrode (51) which is formed on the first principal surface (12A) of the semiconductor chip (12),
a second electrode (54) which is formed on the second principal surface (12B) of the semiconductor chip (12),
a first conductivity-type first region (123, 129) which is formed in the semiconductor chip (12) and electrically connected to the second electrode (54),
a semiconductor element structure (14) which includes a cell trench (15) formed in the active region (64), a control electrode (13) embedded in the cell trench (15) and a second conductivity-type channel region (125) formed laterally in the cell trench (15) and allows a current to flow between the first electrode (51) and the second electrode (54),
a first outer peripheral trench (40) which is annular and formed in the outer peripheral region (63),
a first embedded electrode (43) which is embedded in the first outer peripheral trench (40) and electrically connected to the control electrode (13),
a second outer peripheral trench group (42) which includes a plurality of second outer peripheral trenches (42) that are annular and formed in the outer peripheral region (63) further outside than the first outer peripheral trench (40) and physically separated from the first outer peripheral trench (40), and
a second embedded electrode (45) which is embedded in the second outer peripheral trench (42) and electrically separated from the first embedded electrode (43), in which
a first outer peripheral pitch (P₂) between the first outer peripheral trench (40) and the second outer peripheral trench group (42) is not less than 2.0 μm and not more than 4.0 μm.

### Appendix 2-8

The semiconductor device (1) according to Appendix 2-7 in which
the second outer peripheral trench group (42) includes a first trench (421) which is formed at an interval of the first outer peripheral pitch (P₂) outside from the first outer peripheral trench (40) and a second trench (422) which is formed at an interval of a second outer peripheral pitch (P₃) outside from the first trench (421) and
the second outer peripheral pitch (P₃) is not less than 2.0 μm and not more than 6.0 μm.

### Appendix 2-9

The semiconductor device (1) according to any one of Appendix 2-1 to Appendix 2-8 in which
the first outer peripheral trench (40) includes an inner trench (404) which surrounds the active region (64) and an outer trench (405) which surrounds the inner trench (404).

### Appendix 2-10

The semiconductor device (1) according to Appendix 2-9 including:
a connection electrode (44) which is embedded in the semiconductor chip (12) to connect the first embedded electrode (43) inside the inner trench (404) and the control electrode (13), and
a third electrode (52) which is formed on the first principal surface (12A) of the semiconductor chip (12) and connected to the first embedded electrode (43) inside the inner trench (404) and the first embedded electrode (43) inside the outer trench (405), in which
the first embedded electrode (43) inside the outer trench (405) is electrically connected to the control electrode (13) via the third electrode (52), the first embedded electrode (43) inside the inner trench (404) and the connection electrode (44).

### Appendix 2-11

The semiconductor device (1) according to Appendix 2-9 or Appendix 2-10 in which not less than one and not more than three of the outer trenches (405) are formed.

### Appendix 2-12

The semiconductor device (1) according to any one of Appendix 2-1 to Appendix 2-11 including:
a second conductivity-type well region (122) which is formed at a surface layer portion of the first region (123, 129) from the active region (64) to the outer peripheral region (63) and continues in a lateral direction along the first principal surface (12A) excluding portions at which the first outer peripheral trench (40) and the second outer peripheral trench (42) are formed, in which
the channel region (125) is constituted of a part of the well region (122) and
the well region (122) is formed so as to include internally the first outer peripheral trench (40) and the second outer peripheral trench group (42) and also overlap the first outer peripheral trench (40) and the second outer peripheral trench group (42).

### Appendix 2-13

The semiconductor device (1) according to any one of Appendix 2-1 to Appendix 2-12 including an outer peripheral electrode (53) which is formed on the first principal surface (12A) of the semiconductor chip (12) and connected to the semiconductor chip (12) further outside than the second outer peripheral trench group (42) of the outer peripheral region (63).

### Appendix 2-14

The semiconductor device (1) according to any one of Appendix 2-1 to Appendix 2-13 which has a withstand voltage of not less than 100V.

### Appendix 2-15

The semiconductor device (1) according to any one of Appendix 2-1 to Appendix 2-14 in which
the first region (123, 129) has a specific resistance of not less than 3.5 Ω·cm and not more than 4.5 Ω·cm.

### Appendix 2-16

The semiconductor device (1) according to any one of Appendix 2-1 to Appendix 2-15 in which
the semiconductor chip (12) includes a first conductivity-type semiconductor substrate (127) which has a first impurity concentration and a first conductivity-type epitaxial layer (129) which is formed on the semiconductor substrate (127) and has a second impurity concentration lower than the first impurity concentration to constitute the first region (123) and
the epitaxial layer (129) has a thickness of not less than 7 μm and not more than 15 μm.

### Appendix 2-17

The semiconductor device (1) according to any one of Appendix 2-1 to Appendix 2-16 in which
the first impurity concentration is not less than 1×10¹⁸ cm⁻³ and not more than 1×10²⁰ cm⁻³, and
the second impurity concentration is not less than 1×10¹⁵ cm⁻³ and not more than 1×10¹⁹ cm⁻³.

### Appendix 2-18

The semiconductor device (1) according to any one of Appendix 2-1 to Appendix 2-17 in which
the channel region (125) includes a side portion (124) which forms a side surface of the cell trench (15) and a convex bottom portion (126) which expands outward to the second principal surface (12B) side from a lower end of the side portion (124) so as to separate from the side surface of the cell trench (15) and
the bottom portion (126) of the channel region (125) is positioned further at the first principal surface (12A) side than a lower end (152) of the cell trench (15).

### Appendix 2-19

The semiconductor device (1) according to any one of Appendix 2-1 to Appendix 2-18 in which the first outer peripheral trench (40) is formed at a width (W 2) larger than the cell trench (15).

### Appendix 2-20

The semiconductor device (1) according to Appendix 2-19 in which
the first outer peripheral trench (40) has a depth (D₂) deeper than the cell trench (15).

### Appendix 2-21

The semiconductor device (1) according to any one of Appendix 2-1 to Appendix 2-20 in which
the semiconductor element structure (14) includes a first conductivity-type source region (121), a second conductivity-type channel region (125) and a first conductivity-type drift region (123) which are sequentially formed in a depth direction of the cell trench (15) from the first principal surface (12A) of the semiconductor chip (12) and
the control electrode (13) includes a gate electrode (13) which forms a channel in the channel region (125).

### Appendix 2-22

The semiconductor device (1) according to any one of Appendix 2-1 to Appendix 2-21 in which
the semiconductor chip (12) contains a silicon chip.

### REFERENCE SIGNS LIST

1: Semiconductor device
2: Lead frame
3: Semiconductor element
4: Package
5: Conductive film
6: Insulating film
7: First pad
8: First wire
9: Second pad
10: Second wire
11: First contact plug
12: Semiconductor chip
12A: First principal surface
12B: Second principal surface
13: Gate electrode
14: Transistor cell
14A: Third connection trench
14B: Third connection trench
14C: Third connection trench
15: Gate trench
16: Gate insulating film
17: Interlayer insulating film
18: Source contact
19: Clearance region
20: Clearance region
21: Die pad portion
22: First lead portion
23: Second lead portion
24: Third lead portion
31A: First end surface
31B: First end surface
32A: Second end surface
32B: Second end surface
40: First outer peripheral trench
41: Connection trench
41A: First connection trench
41B: Second connection trench
41C: Third connection trench
42: Second outer peripheral trench
43: First embedded electrode
44: Connection electrode
45: Second embedded electrode
46: Second contact plug
47: Contact hole
48: First side surface
49: Second side surface
50: Step
51: First conductive film
52: Second conductive film
53: Third conductive film
54: Fourth conductive film
61: Clearance region
63: Outer peripheral region
64: Active region
70: First portion
71: Second portion
73: First trench group
74: Second trench group
75: First boundary portion
76: Boundary trench
77: Second boundary portion
78: High concentration impurity region
79: Bottom portion
80: Impurity region
81: Long wire
82: Short wire
83: Depletion layer
84: Arrow
85: Corner portion
86: Corner portion
111: Upper surface
121: First impurity region
122: Second impurity region
123: Third impurity region
124: Side portion
125: Channel region
126: Bottom portion
127: Semiconductor substrate
128: Clearance
129: Epitaxial layer
130: First conductivity-type region
131: Upper surface
132: First potential well region
133: Floating region
134: Third contact plug
135: Outer periphery contact plug
136: Trench group
151: Outer gate trench
152: Lower end
161: First insulating film
162: Second insulating film
163: Third insulating film
191: First barrier film
192: Second barrier film
211A: First side
211B: First side
212A: Second side
212B: Second side
221: First pad portion
222: First lead
231: Second pad portion
232: Second lead
401: First linear portion
402: Second linear portion
403: Corner portion
404: Inner trench
405: Outer trench
411: First connection site
412: Second connection site
413: Third connection site
421: First trench
422: Second trench
423: First linear portion
424: Second linear portion
425: Corner portion
431: Upper surface
451: Upper surface
461: Upper surface
511: Recessed portion
520: Recessed portion
521: Pad electrode portion
522: Finger electrode portion
811: Bonding portion
821: Bonding portion
D₁: Depth
D₂: Depth
D₃: Depth
D_{c1}: Depth
D_{c2}: Depth
P₁: Pitch
P₂: First outer peripheral pitch
P₃: Second outer peripheral pitch
P₄: Third outer peripheral pitch
R: Curvature radius
W₁: Width
W₂: Width
W₃: Width
W₄: Width
W₅: Width
W₆: Width
W₇: Width
W₈: Width

1. A semiconductor device comprising:
a semiconductor chip which has a first principal surface and a second principal surface at the opposite side of the first principal surface in which an active region and an outer peripheral region around the active region are provided at the first principal surface side;
a first electrode which is formed on the first principal surface of the semiconductor chip;
a second electrode which is formed on the second principal surface of the semiconductor chip;
a first conductivity-type first region which is formed in the semiconductor chip and electrically connected to the second electrode;
a semiconductor element structure which includes a cell trench formed in the active region and arrayed at a predetermined cell pitch, a control electrode embedded in the cell trench and a second conductivity-type channel region formed laterally in the cell trench and allows a current to flow between the first electrode and the second electrode;
a first outer peripheral trench which is annular and formed in the outer peripheral region;
a first embedded electrode which is embedded in the first outer peripheral trench and electrically connected to the control electrode;
a second outer peripheral trench group which includes a plurality of second outer peripheral trenches that are annular and formed in the outer peripheral region further outside than the first outer peripheral trench and physically separated from the first outer peripheral trench; and
a second embedded electrode which is embedded in the second outer peripheral trench and electrically separated from the first embedded electrode;
wherein a first outer peripheral pitch between the first outer peripheral trench and the second outer peripheral trench group is not less than 2 times and not more than 4 times the cell pitch.

2. The semiconductor device according to claim 1, wherein
the second outer peripheral trench group includes a first trench which is formed at an interval of the first outer peripheral pitch outside from the first outer peripheral trench and a second trench which is formed at an interval of a second outer peripheral pitch outside from the first trench, and
the second outer peripheral pitch is not less than 2 times and not more than 6 times the cell pitch.

3. The semiconductor device according to claim 2, wherein
the second outer peripheral pitch is smaller than the first outer peripheral pitch.

4. The semiconductor device according to claim 2, wherein the second outer peripheral trench group includes the plurality of second trenches which are arrayed at an interval of a third outer peripheral pitch narrower than the first outer peripheral pitch and the second outer peripheral pitch, and
the third outer peripheral pitch is equal to the cell pitch.

5. The semiconductor device according to claim 1, wherein the cell pitch is not less than 0.8 μm and not more than 1.2 μm and the first outer peripheral pitch is not less than 2.0 μm and not more than 4.0 μm.

6. The semiconductor device according to claim 2, wherein the cell pitch is not less than 0.8 μm and not more than 1.2 μm,
the first outer peripheral pitch is not less than 2.0 μm and not more than 4.0 μm, and
the second outer peripheral pitch is not less than 2.0 μm and not more than 6.0 μm.

7. A semiconductor device comprising:
a semiconductor chip which has a first principal surface and a second principal surface at the opposite side of the first principal surface in which an active region and an outer peripheral region around the active region are provided at the first principal surface side;
a first electrode which is formed on the first principal surface of the semiconductor chip;
a second electrode which is formed on the second principal surface of the semiconductor chip;
a first conductivity-type first region which is formed in the semiconductor chip and electrically connected to the second electrode;
a semiconductor element structure which includes a cell trench formed in the active region, a control electrode embedded in the cell trench and a second conductivity-type channel region formed laterally in the cell trench and allows a current to flow between the first electrode and the second electrode;
a first outer peripheral trench which is annular and formed in the outer peripheral region;
a first embedded electrode which is embedded in the first outer peripheral trench and electrically connected to the control electrode:
a second outer peripheral trench group which includes a plurality of second outer peripheral trenches that are annular and formed in the outer peripheral region further outside than the first outer peripheral trench and physically separated from the first outer peripheral trench; and
a second embedded electrode which is embedded in the second outer peripheral trench and electrically separated from the first embedded electrode;
wherein a first outer peripheral pitch between the first outer peripheral trench and the second outer peripheral trench group is not less than 2.0 μm and not more than 4.0 μm.

8. The semiconductor device according to claim 7, wherein the second outer peripheral trench group includes a first trench which is formed at an interval of the first outer peripheral pitch outside from the first outer peripheral trench and a second trench which is formed at an interval of a second outer peripheral pitch outside from the first trench, and
the second outer peripheral pitch is not less than 2.0 μm and not more than 6.0 μm.

9. The semiconductor device according to claim 1, wherein the first outer peripheral trench includes an inner trench which surrounds the active region and an outer trench which surrounds the inner trench.

10. The semiconductor device according to claim 9 including:
a connection electrode which is embedded in the semiconductor chip and connects the first embedded electrode inside the inner trench and the control electrode, and
a third electrode which is formed on the first principal surface of the semiconductor chip and connected to the first embedded electrode inside the inner trench and the first embedded electrode inside the outer trench, wherein the first embedded electrode inside the outer trench is electrically connected to the control electrode via the third electrode, the first embedded electrode inside the inner trench and the connection electrode.

11. The semiconductor device according to claim 9, wherein not less than one and not more than three of the outer trenches are formed.

12. The semiconductor device according to claim 1 including:
a second conductivity-type well region which is formed at a surface layer portion of the first region from the active region to the outer peripheral region and continues in a lateral direction along the first principal surface excluding portions which form the first outer peripheral trench and the second outer peripheral trench group, wherein the channel region is constituted of a part of the well region, and
the well region is formed so as to include internally the first outer peripheral trench and the second outer peripheral trench group and also overlap the first outer peripheral trench and the second outer peripheral trench group.

13. The semiconductor device according to claim 1 including:
an outer peripheral electrode which is formed on the first principal surface of the semiconductor chip and connected to the semiconductor chip further outside than the second outer peripheral trench group of the outer peripheral region.

14. The semiconductor device according to claim 1 which has a withstand voltage of not less than 100V.

15. The semiconductor device according to claim 1, wherein the first region has a specific resistance of not less than 3.5 Ω·cm and not more than 4.5 Ω·cm.

16. The semiconductor device according to claim 1, wherein the semiconductor chip includes a first conductivity-type semiconductor substrate which has a first impurity concentration and a first conductivity-type epitaxial layer which is formed on the semiconductor substrate and has a second impurity concentration lower than the first impurity concentration to constitute the first region and
the epitaxial layer has a thickness of not less than 7 μm and not more than 15 μm.

17. The semiconductor device according to claim 16, wherein the first impurity concentration is not less than 1×10¹⁸ cm⁻³ and not more than 1×10²⁰ cm⁻³ and the second impurity concentration is not less than 1×10¹⁵ cm⁻³ and not more than 1×10¹⁹ cm⁻³.
